(19) United States
(12) Patent Application Publication
(10) Pub. No.: US 2026/0299426 A1
(43) Pub. Date: Oct. 1, 2026

(54) DRAWING METHOD AND DRAWING DEVICE

(71) Applicant: SCREEN Holdings Co., Ltd., Kyoto (JP)

(72) Inventors: Yoshinao NORIMITSU, Kyoto-shi (JP); Kazuhiro NAKAI, Kyoto-shi (JP)

(73) Assignee: SCREEN Holdings Co., Ltd., Kyoto (JP)

(21) Appl. No.: 19/564,130

(22) Filed: Mar. 11, 2026

(30) Foreign Application Priority Data
Mar. 25, 2025 (JP) 2025-049344

(51) Int. Cl. G03F 7/213; G03F 7/20

(52) U.S. Cl. CPC G03F 7/213; G03F 7/203; G03F 7/2053

(57) ABSTRACT

The drawing method includes: generating drawing data including a wiring pattern and a code pattern representing an identification code of a device; and irradiating modulated light spatially modulated according to the drawing data to a substrate provided with a photosensitive resist film to draw the wiring pattern and the code pattern on the photosensitive resist film. The wiring pattern and the code pattern are drawn at positions not overlapping with each other on the photosensitive resist film. An exposure amount density of the modulated light irradiated onto the substrate is adjusted so that, among apertures formed by developing the photosensitive resist film, a maximum dimension in a depth direction of apertures corresponding to the code pattern is smaller than a maximum dimension in a depth direction of apertures corresponding to the wiring pattern.

### CROSS-REFERENCE TO RELATED APPLICATION

This application claims the priority benefit of Japan application serial no. 2025-049344, filed on Mar. 25, 2025. The entirety of the above-mentioned patent application is hereby incorporated by reference herein and made a part of this specification.

### BACKGROUND

### Technical Field

The disclosure relates to a drawing method and a drawing device.

### Description of Related Art

In recent years, as various devices such as semiconductor devices have become increasingly complex, product issues after the devices are shipped have also been increasing. For this reason, the importance of ensuring device traceability has been increasing. Ensuring traceability is effective for device quality control, device quality assurance, post-shipment trouble response (for example, recall of defective products), post-shipment support, and the like. Additionally, ensuring traceability is also effective for early detection and deterrence of counterfeit products, imitation products, tampering, and the like.

To ensure traceability, individual identification codes need to be assigned to individual devices (specifically, for example, assigned by engraving, printing, and the like). The identification codes assigned to devices are linked with various types of information (material information, manufacturing history, test information, and the like) and managed in databases and the like. In this way, traceability is ensured.

For example, Japanese Patent Application Laid-Open Publication No. 2000-228341 describes engraving identification codes on chips by exposure. Here, first, a reticle is prepared in which an identification code for each of multiple chips provided on a substrate is transferred to a list. Then, the positional relationship between the substrate and the reticle is adjusted so that one of the identification codes transferred to the reticle is positioned above one of the chips, and then one shot of exposure is performed to expose the identification code on the chip. Thereafter, the positional relationship between the substrate and the reticle is changed, and then one shot of exposure is performed again to expose a different identification code on a different chip. In this manner, identification codes are exposed chip by chip while the positional relationship between the substrate and the reticle changes.

Additionally, the following documents are present: Japanese Patent Application Laid-Open Publication No. 2003-188197, Japanese Patent Application Laid-Open Publication No. 2009-105210, Japanese Patent Publication No. 7596139, Japanese Patent Publication No. 7437282, Japanese Patent Application Laid-Open Publication No. 2007-003861, Japanese Patent Application Laid-Open Publication No. 2024-046862, Japanese Patent Application Laid-Open Publication No. 2024-042874

According to the configuration of Japanese Patent Application Laid-Open Publication No. 2000-228341, in order to assign an identification code to each chip, it is necessary to prepare a dedicated reticle and execute a dedicated exposure process. Therefore, manufacturing costs increase and throughput decreases.

### SUMMARY

The disclosure is directed to a drawing method. The drawing method includes: generating drawing data including a wiring pattern and a code pattern representing an identification code of a device; and irradiating modulated light spatially modulated according to the drawing data to a substrate provided with a photosensitive resist film to draw the wiring pattern and the code pattern on the photosensitive resist film. The wiring pattern and the code pattern are drawn at positions that do not overlap with each other on the photosensitive resist film. An exposure amount density of the modulated light irradiated onto the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.

The disclosure is directed to a drawing device. The drawing device includes: a stage, holding a substrate provided with a photosensitive resist film; a drawing head, forming modulated light spatially modulated according to drawing data that includes a wiring pattern and a code pattern representing an identification code of a device, and irradiating the modulated light to the substrate; a relative movement mechanism, causing a relative movement between the stage and the drawing head; and a control part, causing a relative movement between the drawing head and the stage while causing the drawing head to form the modulated light and irradiate the modulated light to the substrate, thereby drawing the wiring pattern and the code pattern on the photosensitive resist film. The wiring pattern and the code pattern are drawn at positions that do not overlap with each other on the photosensitive resist film. An exposure amount density of the modulated light irradiated to the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.

Therefore, an object of the disclosure is to provide a technique that can assign identification codes to devices without requiring extra time and cost.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a side view schematically showing a drawing device according to an embodiment.

FIG. 2 is a plan view schematically showing the drawing device.

FIG. 3 is a block diagram schematically showing an example of an internal configuration of the control part.

FIG. 4 is a view for describing a drawing operation.

FIG. 5 is a view schematically showing a spatial light modulator.

FIG. 6 is a diagram schematically showing an example of a relationship between drive voltage and reflectance.

FIG. 7 is a diagram schematically showing an example of a relationship between exposure amount density and aperture depth.

FIG. 8 is a diagram showing a configuration example of a gradation value table.

FIG. 9 is a diagram for describing a gradation value table.

FIG. 10 is a diagram showing a configuration example of first design data.

FIG. 11 is a diagram showing a configuration example of second design data.

FIG. 12 is a diagram showing a configuration example of drawing data.

FIG. 13 is a diagram for describing a configuration relating to generation of drawing data.

FIG. 14 is a diagram showing a flow of processing relating to drawing data generation.

FIG. 15 is a diagram showing a flow of processes relating to manufacturing of a device.

FIG. 16 is a diagram for describing a wiring layer formation process.

FIG. 17 is a diagram for describing a resist film formation process.

FIG. 18 is a diagram for describing a development process.

FIG. 19 is a diagram for describing a plating process.

FIG. 20 is a diagram schematically showing another example of a relationship between exposure amount density and aperture depth.

FIG. 21 is a diagram showing a configuration example of a gradation value table.

FIG. 22 is a diagram for describing a gradation value table.

### DESCRIPTION OF THE EMBODIMENTS

Hereinafter, embodiments will be described with reference to the accompanying drawings. The components described in these embodiments are merely examples, and are not intended to limit the scope of the disclosure to only those components. The drawings are schematically shown, and for convenience of description, omission of configurations, exaggeration or simplification of dimensions, exaggeration or simplification of numbers, simplification of configurations, and the like are appropriately made. The positional relationships of the configurations shown in the drawings are not necessarily accurately described.

Expressions indicating relative or absolute positional relationships (for example, “in one direction”, “along one direction”, “parallel”, “orthogonal”, “center”, “concentric”, “coaxial”, etc.) include, unless otherwise specified, not only strictly representing the positional relationship, but also states relatively displaced with respect to an angle or a distance within a range where tolerance or an equivalent function can be obtained. Expressions indicating equal states (for example, “same”, “equal”, “homogeneous”, etc.) include, unless otherwise specified, not only quantitatively strictly equal states, but also states where differences are present that allow tolerance or an equivalent function to be obtained. Expressions indicating shapes (for example, “circular” , “elliptical”, “quadrangular” , “cylindrical” , etc.) include, unless otherwise specified, not only geometrically strict representations of the shapes, but also shapes within a range where equivalent effects can be obtained, and may have, for example, irregularities or chamfering. Each expression such as “include”, “comprise”, “be equipped with”, “contain”, “have” is not an exclusive expression that excludes the existence of other components. The expression “at least one of A, B and C” includes “only A”, “only B”, “only C”, “any two of A, B and C”, “all of A, B and C”. In the case where ordinal expressions such as “first” or “second” are used, the terms are used for convenience to facilitate the understanding of the contents of the embodiments, and are not limited to the order that may be generated by the ordinal numbers.

### 1. Drawing Device

### (i) Configuration

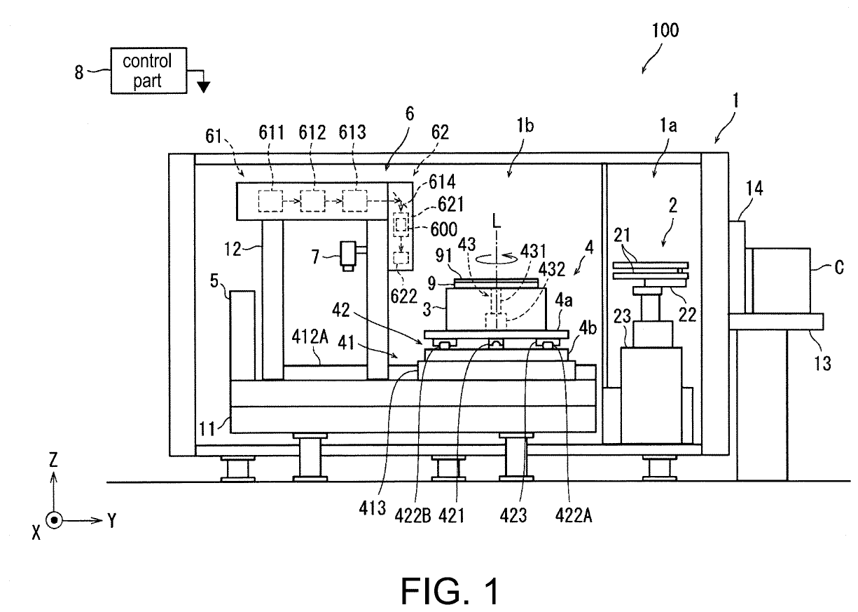

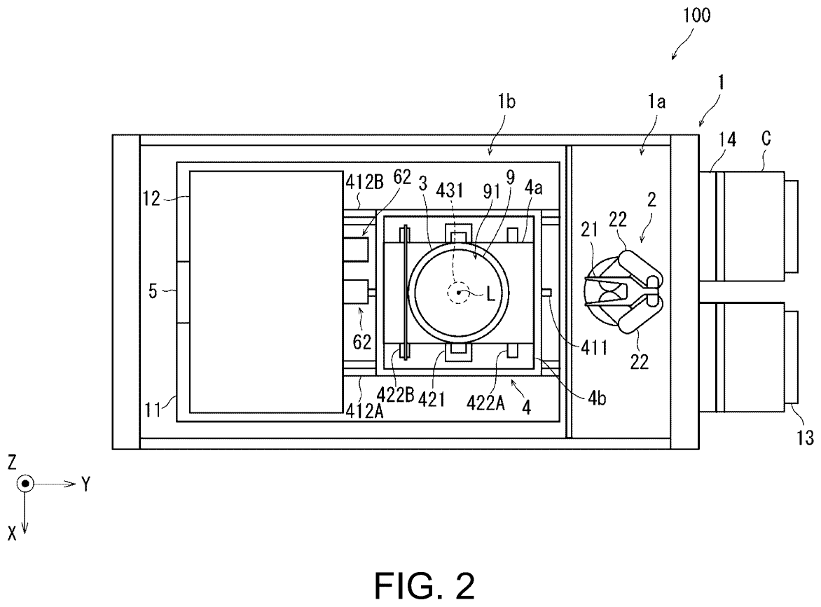

The configuration of a drawing device 100 according to the embodiment will be described with reference to FIG. 1 and FIG. 2. FIG. 1 is a side view schematically showing the drawing device 100. FIG. 2 is a plan view schematically showing the drawing device 100. In each figure referenced below, for the convenience of description, an X-Y-Z coordinate system is appropriately shown where the auxiliary scanning direction is “X-direction”, the main scanning direction is “Y-direction”, and the direction orthogonal to X-direction and Y-direction is “Z-direction”.

The drawing device 100 irradiates an object with light (hereinafter referred to as “modulated light”) spatially modulated according to a pattern to be drawn (exposed) to draw (expose) a pattern on the object. That is, the drawing device 100 scans the object with the modulated light without using a mask to directly draw a pattern (so-called maskless exposure). Such device is also referred to as a direct drawing device, a direct-write type exposure device, etc. Here, the object is a substrate 9 provided with a resist film (photosensitive resist film) 91 formed by a photosensitive material. That is, the drawing device 100 irradiates the substrate 9 with the modulated light to draw a pattern on the resist film 91 provided on the substrate 9.

The drawing device 100 includes a main body frame 1, a transport device 2, a stage 3, a relative movement mechanism 4, a stage position measurement part 5, an optical unit 6, an alignment camera 7, and a control part 8.

### (Main Body Frame 1)

The main body frame 1 forms a housing of the drawing device 100. The interior of the main body frame 1 is partitioned into a transfer region 1a and a processing region 1b. The transport device 2 is disposed in the transfer region 1a. A base 11 is disposed in the processing region 1b. The base 11 is provided with the stage 3, the relative movement mechanism 4, the stage position measurement part 5, and the like. Additionally, a gate-type support frame 12 is erected on the base 11. The support frame 12 supports the optical unit 6, the alignment camera 7, and the like. Furthermore, a cassette mounting part 13 is connected to the main body frame 1. A cassette C is mounted on the cassette mounting part 13. The cassette C is a container that accommodates multiple substrates 9. A load port 14 is provided between the cassette mounting part 13 and the main body frame 1, and serves as an interface for loading and unloading the substrates 9 to and from the cassette C.

### (Transport Device 2)

The transport device 2 transports the substrate 9. The transport device 2 is, for example, a horizontal articulated robot, and includes a pair of hands 21, 21 that hold the substrate 9, and an arm 22 connected to each of the hands 21. Additionally, the transport device 2 includes a drive mechanism 23 for rotating each of the hands 21 and for extending/contracting, rotating, and raising/lowering each arm 22. The transport device 2 takes out the substrate 9 from the cassette C mounted on the cassette mounting part 13 and carries the substrate 9 into the processing region 1b. Additionally, the transport device 2 carries out the substrate 9 from the processing region 1b and stores the substrate 9 in the cassette C mounted on the cassette mounting part 13.

### (Stage 3)

The stage 3 holds the substrate 9. Specifically, the stage 3 has, for example, a flat plate shape, and the substrate 9 is placed on the upper surface of the stage 3 in a horizontal posture (a posture in which the main surface is along a horizontal plane and the thickness direction is along a vertical direction). As an example, multiple suction holes (not shown) are provided on the upper surface of the stage 3. In this case, a negative pressure (suction pressure) is formed in the multiple suction holes. Accordingly, the substrate 9 placed on the upper surface of the stage 3 is fixed to the upper surface.

### (Relative Movement Mechanism 4)

The relative movement mechanism 4 causes a relative movement between the stage 3 and a drawing head 62 (to be described later). The relative movement mechanism 4 includes, for example, a main scanning mechanism 41, an auxiliary scanning mechanism 42, and a rotation mechanism 43.

The main scanning mechanism 41 causes a relative movement of the stage 3 with respect to the drawing head 62 in the main scanning direction (Y-direction). Here, the stage 3 is supported by a lower plate 4b via an upper plate 4a and the auxiliary scanning mechanism 42, and the main scanning mechanism 41 causes a relative movement of the lower plate 4b with respect to the base 11 in the main scanning direction. In this way, the stage 3 supported by the lower plate 4b moves relatively with respect to the base 11 (and thus the drawing head 62) in the main scanning direction. The main scanning mechanism 41 includes, for example, a linear motor 411 and a pair of guide rails 412A, 412B. The linear motor 411 specifically includes, for example, a stator laid on the upper surface of the base 11 in a posture extending in the main scanning direction, and a mover provided on the lower surface of the lower plate 4b. The pair of guide rails 412A, 412B are disposed with the linear motor 411 interposed therebetween, and are laid on the upper surface of the base 11 in a posture extending in the main scanning direction. A bearing 413 (for example, an air bearing) is provided between each of the guide rail 412A, 412B and the upper plate 4a. In such a configuration, when the linear motor 411 is operated, the lower plate 4b moves smoothly in the main scanning direction on the base 11 while being guided by the guide rails 412A, 412B.

The auxiliary scanning mechanism 42 causes a relative movement of the stage 3 with respect to the drawing head 62 in the auxiliary scanning direction (X-direction). As described above, here, the stage 3 is supported by the upper plate 4a, and the auxiliary scanning mechanism 42 causes a relative movement of the upper plate 4a with respect to the lower plate 4b in the auxiliary scanning direction. In this way, the stage 3 supported by the upper plate 4a moves relatively with respect to the base 11 (and thus the drawing head 62) in the auxiliary scanning direction. The auxiliary scanning mechanism 42 includes, for example, a linear motor 421 and a pair of guide rails 422A, 422B. The linear motor 421 specifically includes, for example, a stator laid on the upper surface of the lower plate 4b in a posture extending in the auxiliary scanning direction, and a mover provided on the lower surface of the upper plate 4a. The pair of guide rails 422A, 422B are disposed with the linear motor 421 interposed therebetween, and are laid on the upper surface of the lower plate 4b in a posture extending in the auxiliary scanning direction. A bearing 423 (for example, ball bearing) is provided between each of the guide rails 422A, 422B and the lower plate 4b. In such a configuration, when the linear motor 421 is operated, the upper plate 4a moves smoothly in the auxiliary scanning direction on the lower plate 4b while being guided by the guide rails 422A, 422B.

The rotation mechanism 43 causes a relative rotation of the stage 3 with respect to the drawing head 62 in the rotation direction (rotation direction around Z-axis). Specifically, for example, the rotation mechanism 43 causes a relative rotation of the stage 3 around a rotating shaft L with respect to the upper plate 4a while supporting the stage 3 on the upper plate 4a. In this way, the stage 3 supported by the upper plate 4a rotates relatively around the rotating shaft L with respect to the base 11 (and thus the drawing head 62). The rotating shaft L is, for example, arranged as an axis that passes through the center of the upper surface of the stage 3 (and thus the center of the substrate 9 held on the upper surface) and extends in the vertical direction (Z-axis direction). The rotation mechanism 43 specifically includes, for example, a rotating shaft part 431 and a rotation drive part 432. The rotating shaft part 431 is arranged so that its axis coincides with the rotating shaft L, and is fixed to the stage 3 at the upper end. The rotation drive part 432 is configured to include, for example, a motor, and is connected to the lower end of the rotating shaft part 431 to rotate the rotating shaft part 431 around the axis. In such a configuration, when the rotation drive part 432 rotates the rotating shaft part 431, the stage 3 rotates around the rotating shaft L.

### (Stage Position Measurement Part 5)

The stage position measurement part 5 measures the position of the stage 3 (for example, the position in the main scanning direction and the position in the rotation direction). The stage position measurement part 5 specifically includes, for example, an emission part, a light receiving part, and a measurement part (none of which is shown). The emission part emits laser light toward the stage 3 from outside the stage 3. The light receiving part receives reflected light which is the laser light emitted from the emission part reflected by the stage 3. The measurement part specifies the position of the stage 3 based on, for example, the interference between the reflected light received by the light receiving part and the emitted light emitted from the emission part (the so-called interference-type laser length measuring device). However, the stage position measurement part 5 is not necessarily limited to an interference-type laser length measuring device, and may be configured by using, for example, a linear scale or the like.

### (Optical Unit 6)

The optical unit 6 includes a light source part 61 and a drawing head (head part) 62. The light source part 61 is, for example, accommodated in a box attached to the upper surface of the top plate of the support frame 12. The drawing head 62 is, for example, accommodated in a box attached to (provided on) the side wall of the top plate of the support frame 12.
a. Light Source Part 61

The light source part 61 specifically includes, for example, a laser drive part 611, a laser oscillator 612, and an illumination optical system 613. The laser drive part 611 drives the laser oscillator 612. The laser oscillator 612 receives driving from the laser drive part 611 and emits laser light (spot beam) from an output mirror (not shown). The spot beam emitted from the laser oscillator 612 enters the illumination optical system 613. The illumination optical system 613 shapes the spot beam that enters here into linear light (line beam). The line beam is specifically light having a substantially uniform intensity distribution and a band-shaped light beam cross-section. The line beam shaped by the illumination optical system 613 enters the drawing head 62. Specifically, the line beam shaped by the illumination optical system 613 enters a spatial light modulation unit 621 (to be described later) included in the drawing head 62 via a mirror 614 at a predetermined angle.
b. Drawing Head 62

The drawing head 62 forms modulated light and irradiates the substrate 9 held on the stage 3 with the modulated light. The drawing head 62 includes, for example, a spatial light modulation unit 621 and a projection optical system 622.

The spatial light modulation unit 621 applies spatial modulation to light (incident light) entering here according to drawing data Q (to be described later) to form modulated light. Here, “applying spatial modulation to incident light” means changing the spatial distribution of the incident light. The spatial distribution of the incident light includes the amplitude of light, the phase of light, polarization, and the like. In other words, “applying spatial modulation to the incident light” means changing at least one of the amplitude of the incident light, the phase of the incident light, the polarization of the incident light, and the like. The spatial light modulation unit 621 applies spatial modulation to the incident light to separate the incident light into light that contributes to drawing (hereinafter referred to as “drawing light”) and light that does not contribute to drawing (hereinafter referred to as “unnecessary light”), thereby forming the modulated light.

The projection optical system 622 guides the modulated light formed by the spatial light modulation unit 621 and emitted from the spatial light modulation unit 621 to the substrate 9 held on the stage 3, and irradiates the substrate 9. The projection optical system 622 includes, for example, a blocking plate. The blocking plate is a plate-shaped member formed with a through hole, and blocks the unnecessary light while allowing the drawing light to pass through. That is, the unnecessary light included in the modulated light emitted from the spatial light modulation unit 621 is blocked by the blocking plate, and the drawing light included in the modulated light passes through the through holes of the blocking plate. As a result, the unnecessary light does not reach the substrate 9 held on the stage 3, and the drawing light reaches the substrate 9 held on the stage 3. The projection optical system 622 may further include a lens (objective lens) that forms an image of the modulated light on the substrate 9 at a predetermined magnification, optical components (for example, a zoom lens, a reduction projection optical system) for adjusting (expanding or narrowing) the width of the modulated light, and the like.

### (Alignment Camera 7)

The alignment camera 7 captures an image of the substrate 9 held on the stage 3 to acquire imaging data of the substrate 9. The alignment camera 7 is specifically configured by, for example, a digital camera. One or more alignment marks (not shown) are provided on the upper surface of the substrate 9. By detecting the alignment marks from the imaging data acquired by the alignment camera 7, the position and posture of the substrate 9 held on the stage 3 (for example, the position in the main scanning direction, the position in the auxiliary scanning direction, the angle in the rotation direction, and the like) are specified.

### (Control Part 8)

The control part 8 controls the operation of each part (the transport device 2, the stage 3, the relative movement mechanism 4, the stage position measurement part 5, the optical unit 6, the alignment camera 7, and the like) included in the drawing device 100 and performs various arithmetic processing. The control part 8 is configured by, for example, a general computer having an electric circuit (electronic circuit), a microcomputer, or the like.

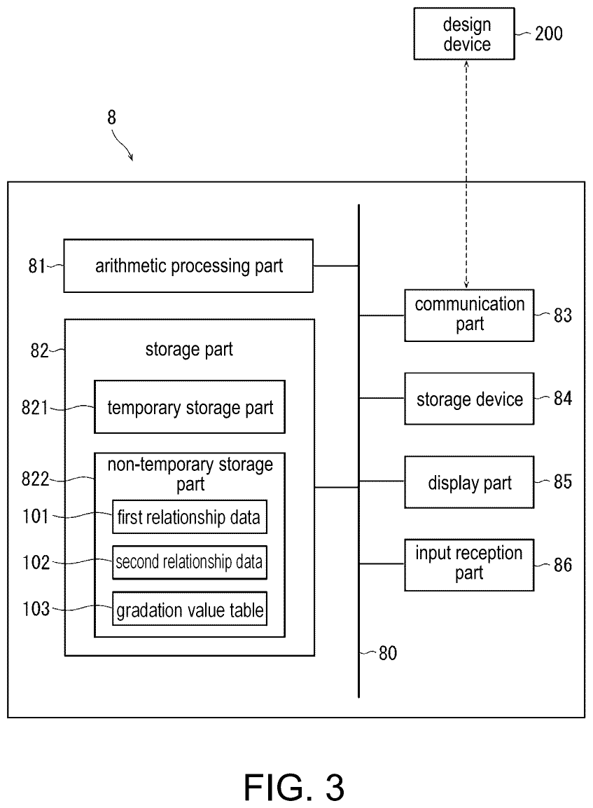

A configuration example of the control part 8 will be described with reference to FIG. 3. FIG. 3 is a block diagram schematically showing an example of the internal configuration of the control part 8. The control part 8 may be realized by multiple computers cooperating with each other, and, in this case, the computers may be provided at positions separated from each other.

The control part 8 includes an arithmetic processing part 81 and a storage part 82. The arithmetic processing part 81 and the storage part 82 are connected to each other via, for example, a bus 80.

The arithmetic processing part 81 performs various arithmetic processing (data processing) (that is, functions as an arithmetic circuit). The arithmetic processing part 81 includes, for example, one or more processors. The processor includes, for example, one or more circuits or units configured to execute arithmetic operations or processing by executing instructions stored in the storage part 82. Also, the processor includes, for example, at least one of a central processor unit (CPU), an application-specific integrated circuit (ASIC), a field-programmable gate array (FPGA), a digital signal processor (DSP), a digital flow processor (DFP), a micro controller unit (MCU), a graphics processing unit (GPU), and a neural processing unit (NPU). The arithmetic processing part 81 may be realized by multiple processors cooperating with each other, and in this case, the processors may be provided at positions separated from each other.

The storage part 82 includes a temporary storage part (for example, a random access memory (RAM)) 821 and a non-temporary storage part (for example, a read only memory (ROM)) 822. The temporary storage part 821 may be used, for example, as a working area at the time of the arithmetic processing part 81 performing processing (data processing). The non-temporary storage part 822 may store, for example, a program that defines processing executed by the control part 8. In this case, for example, with the arithmetic processing part 81 executing the program, the processing defined in the program is executed in the control part 8. That is, with the arithmetic processing part 81 executing the program, functional blocks defined in the program (for example, circuits that perform the processing defined in the program) are realized in the control part 8. However, part or all of the processing to be executed in the control part 8 (functional blocks to be realized in the control part 8) may be executed (realized) by hardware such as a dedicated logic circuit (for example, a dedicated processor).

The control part 8 may further include at least one of a communication part 83, a storage device 84, a display part 85, and an input reception part 86. At least one of the communication part 83, the storage device 84, the display part 85, and the input reception part 86 may be mutually connected to the arithmetic processing part 81 and the storage part 82 via the bus 80. The communication part 83 realizes a data communication function. The communication part 83 includes, for example, a data communication function via a local area network (LAN) or the like. The storage device 84 includes, for example, at least one of a magnetic disk, an optical disk, a flash memory, a memory card, a hard disk device, and the like. The display part 85 displays various data and various images, and can be realized using, for example, a general CRT monitor, a liquid crystal display, a touch panel, and the like. The input reception part 86 receives the input of various commands from an operator, and can be realized by using, for example, various buttons, various switches, various keys, a mouse, a keyboard, a touch panel, a microphone, a recording medium reading device, and the like.

### (ii) Drawing Operation

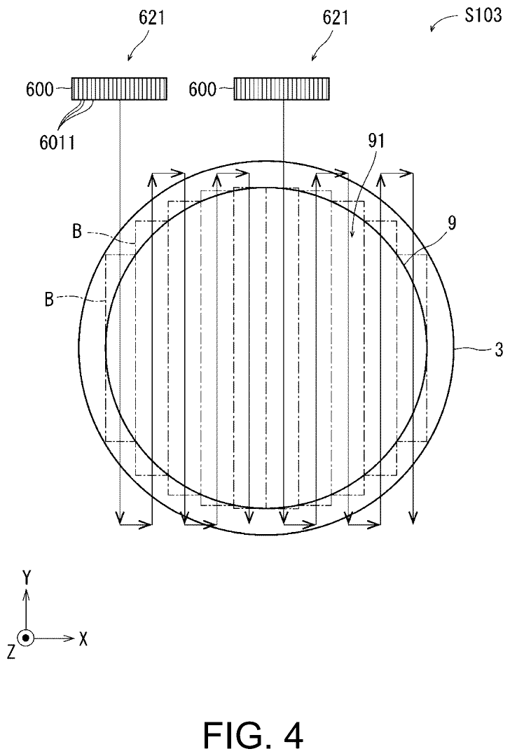

The operation (drawing operation) of the drawing device 100 will be described with reference to FIG. 4 in addition to FIG. 1 and FIG. 2. FIG. 4 is a view for describing the drawing operation. In the example of the figure, a case where the drawing device 100 includes two drawing heads 62 is illustrated, but the number of the drawing heads 62 included in the drawing device 100 may be one, or may be three or more. The spatial light modulation unit 621 included in each drawing head 62 is arranged in a posture so that the array direction (to be described later) of multiple ribbons 6011 included in the spatial light modulator 600 is along the auxiliary scanning direction.

The drawing operation proceeds under the control of the control part 8. That is, the drawing operation proceeds with the control part 8 controlling each part included in the drawing device 100.

First, the cassette C storing the substrate 9 to be processed is mounted on the cassette mounting part 13. The substrate 9 is provided with the resist film 91. Subsequently, the transport device 2 takes out the substrate 9 from the cassette C and mounts the substrate 9 on the stage 3. When the substrate 9 is mounted on the stage 3, the stage 3 holds the substrate 9. Subsequently, the stage 3 is arranged at a predetermined initial position. Thereafter, the alignment camera 7 captures an image of the substrate 9 held by the stage 3 and acquires the imaging data of the substrate 9. The control part 8 detects an alignment mark from the acquired imaging data, specifies the position and the posture of the substrate 9 held by the stage 3, and adjusts the relative position of the stage 3 (and consequently the substrate 9 held on the stage 3) with respect to the drawing head 62 based on the specified position and posture of the substrate 9. In this way, the drawing head 62 and the substrate 9 are arranged in an intended positional relationship.

Subsequently, main scanning is performed. That is, the relative movement mechanism 4 moves relatively the stage 3 (and consequently the substrate 9 held on the stage 3) with respect to the drawing head 62 along the main scanning direction (Y-direction) in the forward direction (for example, −Y direction). In parallel with the main scanning, the modulated light is emitted from each drawing head 62. Specifically, the control part 8 reads out a portion (target data portion) corresponding to a stripe region B to be drawn in the main scanning from the drawing data Q (to be described later). The control part 8 controls the spatial light modulation unit 621 according to the read target data portion to form modulated light that has been spatially modulated according to the target data portion. The modulated light formed by the spatial light modulation unit 621 is irradiated to the substrate 9 (specifically, the resist film 91) through the projection optical system 622. When the drawing head 62 traverses the substrate 9 along the main scanning direction while emitting the modulated light intermittently or continuously, the modulated light is irradiated to the stripe region B (the stripe region B being a band-shaped region extending in the main scanning direction). In this way, the pattern described in the target data portion of the drawing data Q is drawn (exposed) on the stripe region B. In the case where two drawing heads 62 are provided, for example, the two drawing heads 62 simultaneously traverse the substrate 9, thereby performing pattern drawing for the respective two stripe regions B in parallel.

When the main scanning accompanied by the emission of modulated light ends, auxiliary scanning is performed. That is, the relative movement mechanism 4 relatively moves the stage 3 with respect to the drawing head 62 along the auxiliary scanning direction (X-direction) in a predetermined direction (for example, −X direction) by a distance corresponding to the dimension of the stripe region B in the width direction (auxiliary scanning direction).

Subsequently, main scanning is performed again. That is, the relative movement mechanism 4 moves relatively the stage 3 (and consequently the substrate 9 held on the stage 3) with respect to the drawing head 62 along the main scanning direction (Y-direction) in the return direction (for example, −Y direction). Here also, in parallel with the main scanning, the modulated light is emitted from the drawing head 62. When the drawing head 62 traverses the substrate 9 along the main scanning direction while emitting modulated light intermittently or continuously, the modulated light is irradiated to the stripe region B (the stripe region B adjacent to the stripe region B that has been irradiated with the modulated light in the previous main scanning). That is, a pattern is drawn on the stripe region B.

Similarly thereafter, main scanning in the forward direction accompanied by the emission of the modulated light and main scanning in the return direction accompanied by the emission of the modulated light are alternately performed with auxiliary scanning interposed therebetween. By performing main scanning accompanied by the emission of modulated light a predetermined number of times, a pattern is drawn on the entire substrate 9.

When a pattern is drawn on the entire substrate 9, the stage 3 releases the holding of the substrate 9. Thereafter, the transport device 2 picks up the substrate 9 placed on the stage 3 and stores the substrate 9 in the cassette C.

With the above, the drawing operation for one substrate 9 is completed. In the drawing device 100, such drawing operation is normally performed repeatedly. That is, when the drawing operation for one substrate 9 ends, the drawing operation for another new substrate 9 is subsequently performed.

### 2. Multi-Gradation Drawing

In the drawing device 100, multi-gradation drawing (gradation exposure) is possible. A configuration related to multi-gradation drawing will be described.

### (i) Spatial Light Modulator 600

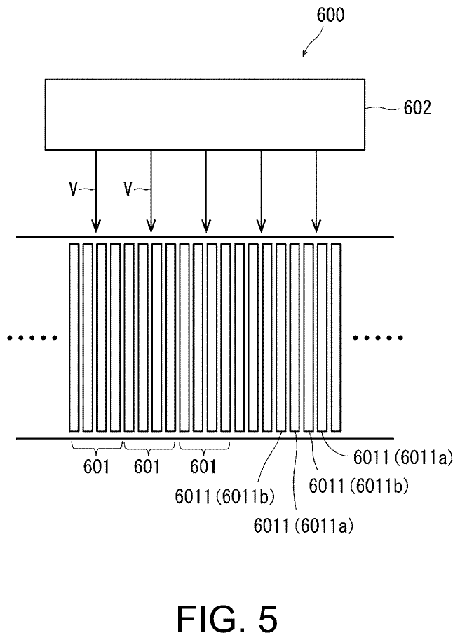

The spatial light modulation unit 621 includes the spatial light modulator 600. A configuration example of the spatial light modulator 600 will be described with reference to FIG. 5. FIG. 5 is a diagram schematically showing the spatial light modulator 600.

The spatial light modulator 600 is, for example, a diffraction grating type spatial light modulator (diffraction grating type light modulation element). The diffraction grating type spatial modulator includes a diffraction grating that can change the depth of the grating. As an example, the spatial light modulator 600 can be configured by using a grating light valve (“GLV”, which is a registered trademark).

The spatial light modulator 600 specifically includes, for example, multiple modulation units 601 and a driver circuit unit 602.

The modulation units 601 are arranged in a predetermined direction. Each modulation unit 601 includes, for example, a configuration in which multiple ribbons (mirrors) 6011 having reflective films formed on the surfaces are arranged in the predetermined direction (that is, the array direction of the modulation units 601). The ribbons 6011 include fixed ribbons 6011a and flexible ribbons 6011b, and the fixed ribbons 6011a and the flexible ribbons 6011b are alternately arranged along the array direction. As an example, the spatial light modulator 600 has a dimension of 4 mm in the array direction (width direction) of the ribbons 6011, and 8000 ribbons 6011 are arranged therein. Also, as an example, one modulation unit 601 is configured by four ribbons 6011. In this case, 2000 modulation units 601 are provided in the range of 4 mm, and the minimum resolution in the width direction is 2 μm (=4 mm/2000 units). Such a fine structure is manufactured by using, for example, semiconductor device manufacturing technology.

The driver circuit unit 602 applies a voltage V (hereinafter referred to as “drive voltage”) to each modulation unit 601 (specifically, to the flexible ribbon 6011b included in each modulation unit 601). The driver circuit unit 602 can apply the drive voltage V individually (independently) to each of the multiple modulation units 601 included in the spatial light modulator 600. That is, the drive voltage V for each modulation unit 601 is individually controlled. The driver circuit unit 602 applies a specified drive voltage V to a specified modulation unit 601 in accordance with an instruction from the control part 8.

### (ii) Relationship Between Drive Voltage V and Reflectance R

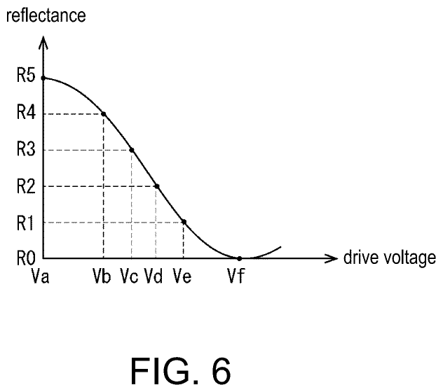

Next, the relationship between the drive voltage V and the reflectance R will be described with reference to FIG. 6. FIG. 6 is a diagram schematically showing an example of the relationship between the drive voltage V and the reflectance R. However, “reflectance R” is the light amount ratio between the drawing light emitted from the modulation unit 601 and the light (incident light) incident on the modulation unit 601 (reflectance R =light amount of drawing light/light amount of incident light). That is, the reflectance R is a value indicating what proportion of the incident light that enters the modulation unit 601 is emitted as drawing light.

In the case where no drive voltage V is applied to the modulation unit 601 (or the applied drive voltage V is sufficiently small), the flexible ribbon 6011b does not bend. In the case where the flexible ribbon 6011b does not bend, the surface of the modulation unit 601 becomes a flat surface (mirror surface). Therefore, the incident light that enters the modulation unit 601 undergoes regular reflection without diffraction. That is, first-order or higher diffracted light does not occur, and only zero-order diffracted light (i.e., regularly reflected light) occurs. Here, the zero-order diffracted light reaches the substrate 9, and the first-order or higher diffracted light does not reach the substrate 9. That is, the zero-order diffracted light becomes light that contributes to drawing (i.e., drawing light), and the first-order or higher diffracted light becomes light that does not contribute to drawing (i.e., unnecessary light). That is, when the flexible ribbon 6011b does not bend, the reflectance R becomes 100%. The drive voltage V at which such a state is formed is hereinafter referred to as “minimum voltage Va”. That is, when the drive voltage V is set to the minimum voltage Va, a reflectance R5 becomes 100% (R5=100%). The minimum voltage Va is, for example, zero.

When the drive voltage V applied to the modulation unit 601 becomes larger than the minimum voltage Va, the flexible ribbon 6011b bends downward, and a groove is formed on the surface of the modulation unit 601. When a groove is formed, a portion of the incident light that enters the modulation unit 601 becomes first-order or higher diffracted light (i.e., unnecessary light), and the remainder becomes zero-order diffracted light (i.e., drawing light). That is, the reflectance R becomes smaller than 100%. The bending amount of the flexible ribbon 6011b (that is, the depth of the groove) becomes larger (the depth of the groove becomes deeper) as the applied drive voltage V becomes larger. As the depth of the groove increases, the proportion of first-order or higher diffracted light that occurs becomes higher, and the proportion of zero-order diffracted light that occurs becomes lower. That is, as the applied drive voltage V becomes larger, the reflectance R becomes smaller.

When the drive voltage V is set to a predetermined value that is sufficiently large, the flexible ribbon 6011b bends sufficiently significantly, and the depth of the groove becomes sufficiently deep. For example, when the depth of the groove becomes one-fourth or more of the wavelength of the incident light, all of the incident light that enters the modulation unit 601 undergoes diffraction. That is, zero-order diffracted light (i.e., drawing light) does not occur, and only first-order or higher diffracted light (i.e., unnecessary light) occurs. That is, the reflectance R becomes 0%. The drive voltage V at which such a state is formed is hereinafter referred to as “maximum voltage Vf”. That is, when the drive voltage V is set to the maximum voltage Vf, the reflectance R0 becomes 0% (R0=0%).

In this way, in the spatial light modulator 600, the reflectance R of the modulation unit 601 changes according to the drive voltage V applied to the modulation unit 601. Therefore, by controlling the drive voltage V applied to the modulation unit 601, the reflectance R of the modulation unit 601 can be controlled. Furthermore, by individually controlling the drive voltage V applied to each of the modulation units 601, the reflectance R of each modulation unit 601 can be individually controlled. The correspondence relationship between the drive voltage V and the reflectance R (specifically what values they correspond to) differs depending on device conditions (the type of spatial light modulator 600, the type of light source, etc.), but once the device conditions are determined, the correspondence relationship between the two is uniquely determined. Here, the correspondence relationship between the two based on the device conditions is specified in advance by experiments, simulations, calculations, etc., and the specified correspondence relationship is stored in the storage part 82 as first relationship data 101 (FIG. 3).

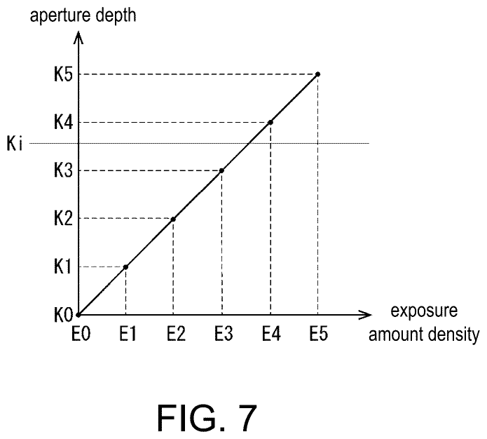

Relationship between exposure amount density E and aperture depth K Next, the relationship between the exposure amount density E and the aperture depth K will be described with reference to FIG. 7. FIG. 7 is a diagram schematically showing an example of the relationship between the exposure amount density E and the aperture depth K. However, “exposure amount density E” is the amount of light per unit area of the drawing light irradiated to the resist film 91. Also, “aperture depth K” is the dimension in the depth direction (dimension in the thickness direction of the resist film 91) of the aperture formed by developing the position where the drawing light was irradiated (exposed).

The exposure amount density E and the aperture depth K have a correspondence relationship. For example, in the case where the resist film 91 is formed by a positive-type photosensitive material, the aperture depth K increases as the exposure amount density E increases. However, while FIG. 7 illustrates a case where the exposure amount density E and the aperture depth K have a proportional relationship, the two do not necessarily have a proportional relationship. The correspondence relationship between the exposure amount density E and the aperture depth K (specifically what values they correspond to) differs depending on device conditions and processing conditions (forming material of the resist film 91, wavelength of light emitted from the light source part 61, etc.), but once the device conditions and the processing conditions are determined, the correspondence relationship between the two is uniquely determined. Here, the correspondence relationship between the two based on the device conditions and processing conditions is specified in advance by experiments, simulations, calculations, etc., and the specified correspondence relationship is stored in the storage part 82 as second relationship data 102 (FIG. 3). The fact that the exposure amount density E and the aperture depth K have a correspondence relationship means that the aperture depth K can be changed by changing the exposure amount density E.

As described above, the exposure amount density E is the amount of light per unit area of the drawing light irradiated to the resist film 91. Specifically, the exposure amount density E is a value obtained by multiplying the light amount of the incident light of the modulation unit 601 by the reflectance R and the exposure time, and dividing the obtained value by the irradiation area. The light amount of the incident light is a constant defined by the light source part 61 and the like. The exposure time is a value defined from the relative movement speed between the modulation unit 601 and the substrate 9 (that is, the relative movement speed between the drawing head 62 and the stage 3). For example, in the case where the relative movement speed between the drawing head 62 and the stage 3 is constant in main scanning accompanied by emission of the modulated light, the exposure time becomes a constant. Also, the irradiation area is the area of the region irradiated by the drawing light coming from the modulation unit 601, and is a constant defined by the projection optical system 622 and the like. Therefore, once the light amount of the incident light, the exposure time, and the irradiation area are determined, the reflectance R and the exposure amount density E can be associated by using the respective values thereof. The fact that the reflectance R and the exposure amount density E have a correspondence relationship means that the exposure amount density E (and consequently, the aperture depth K) can be changed by changing the reflectance R.

As described above, in the spatial light modulator 600, the reflectance R of each modulation unit 601 can be individually controlled by individually controlling the drive voltage V for each modulation unit 601. The fact that the reflectance R of each modulation unit 601 can be individually controlled means that the exposure amount density E at the position irradiated by the drawing light emitted from each modulation unit 601 (and consequently, the aperture depth K of the aperture formed by developing the position) can be individually controlled. That is, by using the spatial light modulator 600, drawing with multiple gradation values G (multi-gradation) including intermediate gradations becomes possible.

### (iv) Multi-Gradation Drawing Mode

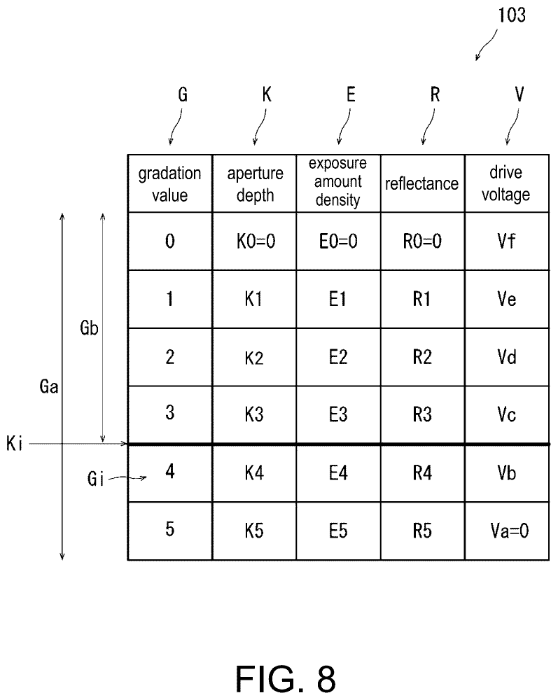

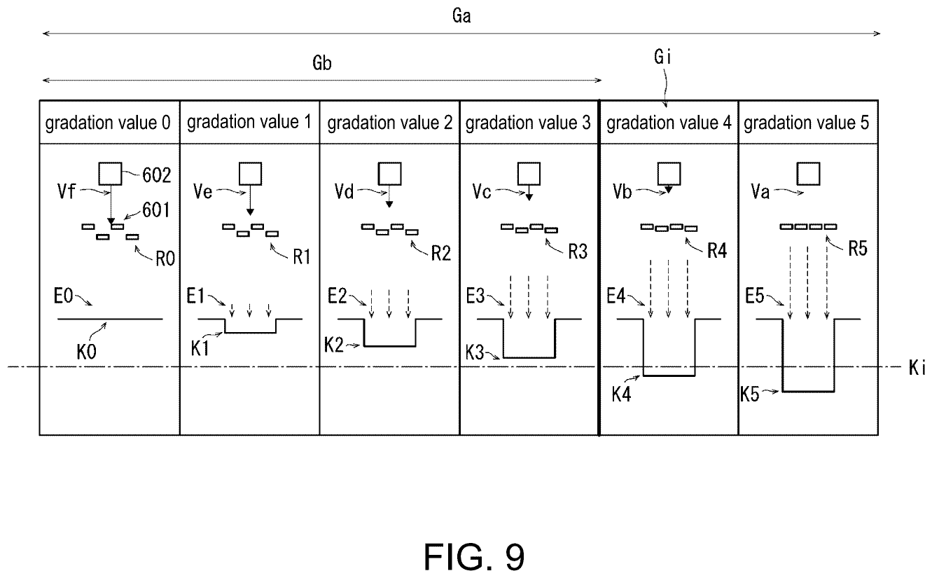

A mode for performing multi-gradation drawing will be described with reference to FIG. 8 and FIG. 9. FIG. 8 is a diagram showing a configuration example of the gradation value table 103. FIG. 9 is a diagram for describing the gradation value table 103.

As described above, in the drawing device 100, the modulated light is formed by applying spatial modulation according to the drawing data Q to the incident light, and by irradiating the modulated light to the substrate 9 (specifically, the resist film 91), the pattern described in the drawing data Q is drawn on the resist film 91. Here, the drawing data Q is pixel data (dot data) in which a pattern to be drawn on the substrate 9 (specifically, the resist film 91) is described, and, for example, the information indicating the positions where light should be irradiated is described in pixel units. However, the drawing data Q is pixel data expressed in multi-gradation, and a gradation value G is assigned to each pixel of the drawing data Q. By using the spatial light modulator 600, drawing with an arbitrary number of gradations is possible, but here, for example, it is assumed that the number of gradations that can be drawn is specified as “6”. In this case, the drawing data Q is pixel data of 6 gradations, and each pixel of the drawing data Q is assigned with a gradation value G of any one of “0” to “5”, for example.

The pattern described in the drawing data Q is drawn with the gradation value G assigned to each pixel. When drawing is performed according to the gradation value G, here, for example, the gradation value table 103 is used. The gradation value table 103 is a table in which various parameters corresponding to each gradation value G are specified, and is stored in the storage part 82 (FIG. 3). In the gradation value table 103, the respective gradation values G are associated with mutually different aperture depths K. The correspondence relationship is arbitrarily specified. However, the value of the aperture depth K corresponding to one of the gradation values G is set to zero. Here, for example, the value of the aperture depth K0 corresponding to the gradation value G “0” is set to zero (K0=0), and the association therebetween is made such that the larger the gradation value G, the larger the value of the aperture depth K. Also, in the gradation value table 103, each aperture depth K (aperture depth K associated with each gradation value G) is linked with the corresponding exposure amount density E. As described above, the correspondence relationship between the aperture depth K and the exposure amount density E is specified by the second relationship data 102. Also, in the gradation value table 103, each exposure amount density E (exposure amount density E associated with each aperture depth K) is linked with the corresponding reflectance R. The reflectance R corresponding to the exposure amount density E is calculated based on the light amount of incident light, exposure time, irradiation area, and the like. Also, in the gradation value table 103, each reflectance R (reflectance R associated with each exposure amount density E) is linked with the corresponding drive voltage V. As described above, the correspondence relationship between the reflectance R and the drive voltage V is specified by the first relationship data 101.

Now, focusing on an arbitrary pixel of the drawing data Q (hereinafter referred to as “target pixel”), the position on the substrate 9 corresponding to the target pixel is referred to as “target position”, and the modulation unit 601 responsible for drawing the target position is referred to as “target modulation unit 601”. In forming the modulated light, the drive voltage V linked with the gradation value G assigned to the target pixel (that is, the drive voltage V linked with the gradation value G in the gradation value table 103) is applied to the target modulation unit 601. Then, the reflectance R of the target modulation unit 601, and consequently, the exposure amount density E of the modulated light irradiated to the target position, follows the gradation value G assigned to the target pixel. In this way, a pattern is drawn at the target position with the gradation value G assigned to the target pixel. As a result, the aperture depth K of the aperture formed at the target position by performing development becomes the value linked with the gradation value G assigned to the target pixel (that is, the value of the aperture depth K linked with the gradation value G in the gradation value table 103).

For example, in the case where the gradation value G assigned to the target pixel is “5”, the drive voltage V is not applied to the target modulation unit 601 (the drive voltage V is set to the minimum voltage Va). At this time, the reflectance R5 of the target modulation unit 601 becomes 100%, and the exposure amount density E of the modulated light irradiated to the target position becomes the exposure amount density E5 according to the gradation value G “5” assigned to the target pixel. Consequently, the aperture depth K of the aperture formed at the target position by performing development becomes the aperture depth K5 according to the gradation value G “5” assigned to the target pixel.

In the gradation value table 103, in the case where the correspondence between the gradation value G and the aperture depth K is made so that the smaller the gradation value G, the smaller the value of the aperture depth K, the smaller the gradation value G assigned to the target pixel, the larger the drive voltage V applied to the target modulation unit 601, and the smaller the reflectance R of the target modulation unit 601. The smaller the reflectance R becomes, the smaller the exposure amount density E of the modulated light irradiated to the target position becomes, and the smaller (shallower) the aperture depth K of the aperture formed at the target position by performing development becomes.

In the case where the gradation value G assigned to the target pixel is “0”, the maximum voltage Vf is applied to the target modulation unit 601 (the drive voltage V is set to the maximum voltage Vf). At this time, the reflectance R0 of the target modulation unit 601 becomes 0%, no light is irradiated to the target position, and the exposure amount density E0 becomes zero. That is, the exposure amount density E of the modulated light irradiated to the target position becomes the exposure amount density E0 (E0=0) according to the gradation value G “0” assigned to the target pixel. Therefore, even when development is performed, the resist film 91 at the target position does not dissolve (no aperture is formed), and the aperture depth K of the aperture formed at the target position becomes zero. That is, the aperture depth K of the aperture formed at the target position by performing development becomes the aperture depth K0 (K0=0) according to the gradation value G “0” assigned to the target pixel.

### 3. Generation Mode of Drawing Data

### (i) Data Related to Generation of Drawing Data Q

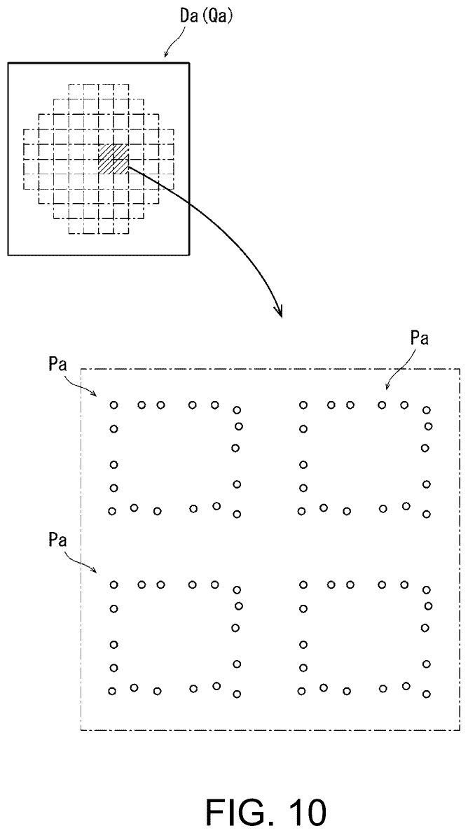

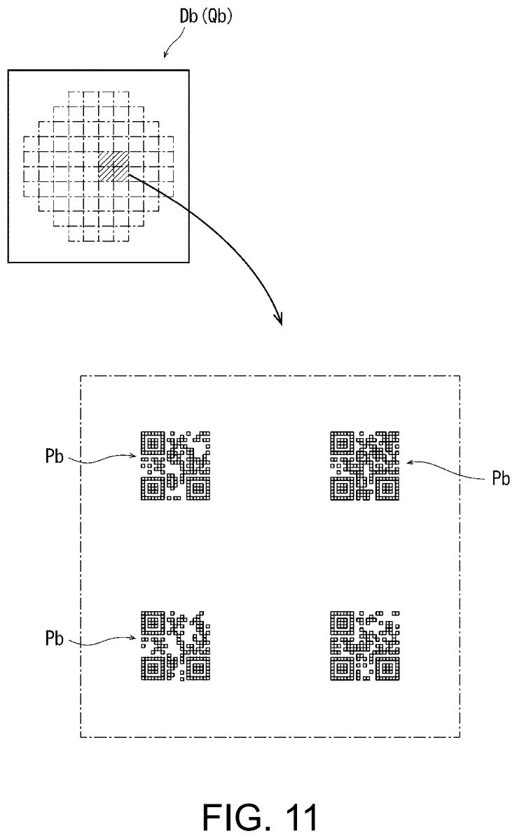

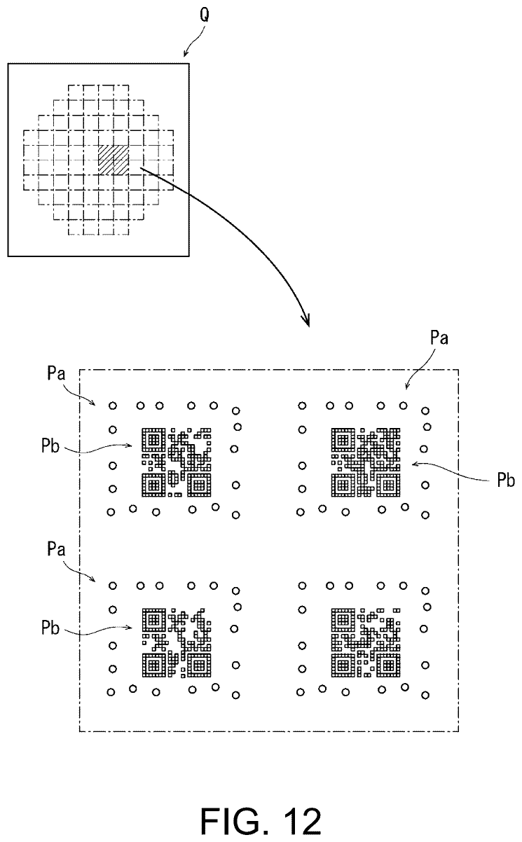

Various data related to generation of the drawing data Q (first design data Da, first pixel data Qa, second design data Db, second pixel data Qb, and drawing data Q) will be described with reference to FIG. 10 to FIG. 12. FIG. 10 is a diagram showing a configuration example of the first design data Da. FIG. 11 is a diagram showing a configuration example of the second design data Db. FIG. 12 is a diagram showing a configuration example of the drawing data Q.

### (First Design Data Da)

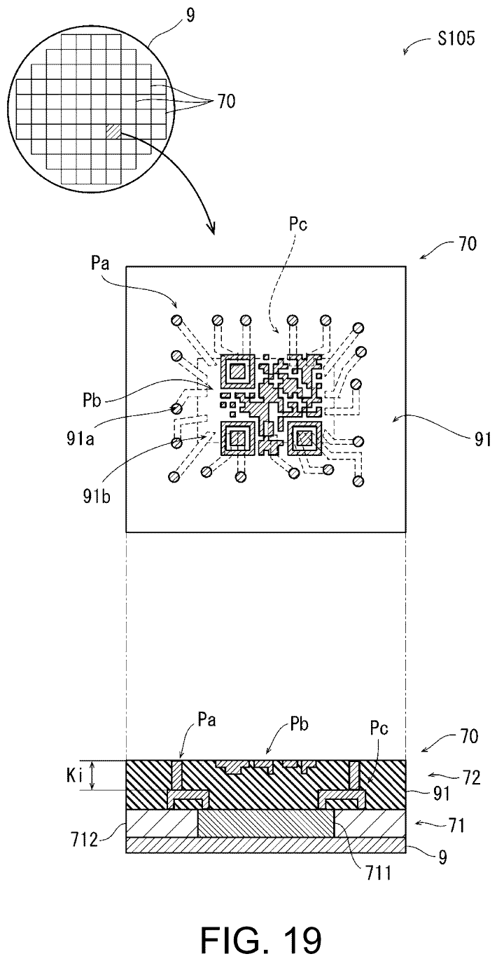

The first design data Da is the design data of a wiring pattern formed in the resist film 91 provided on the substrate 9. Here, a device 70 manufactured on the substrate 9 is, for example, a semiconductor device (FIG. 19). The device 70 includes a wiring layer 71 provided with a wiring pattern (hereinafter referred to as “lower wiring pattern”) Pc. The wiring layer 71 includes, for example, a chip (for example, a silicon chip) 711 and an interposer 712. The resist film 91 is provided on the wiring layer 71 and serves as a redistribution layer (RDL) 72. That is, the wiring pattern defined in the first design data Da is a wiring pattern (hereinafter referred to as “redistribution pattern”) Pa formed in the redistribution layer 72. The redistribution pattern Pa includes, for example, a via. The via is a through hole that connects the lower wiring pattern Pc with the upper surface of the redistribution layer 72. That is, the via is a hole that penetrates through a portion of the redistribution layer 72 covering the lower wiring pattern Pc in the thickness direction, opens at a predetermined position on the upper surface of the redistribution layer 72 at the upper end, and opens at a position facing the lower wiring pattern Pc at the lower end.

The first design data Da is vector data (data in a vector format). That is, in the first design data Da, the redistribution pattern Pa (specifically, the position, shape, dimension, etc. of the redistribution pattern Pa) is described in a vector format. As an example, the first design data Da is CAD data generated by using computer-aided design (CAD). However, here, multiple devices 70 are manufactured on one substrate 9 (FIG. 19). Therefore, in the first design data Da, multiple redistribution patterns Pa to be formed on one device 70 are described, for example, arranged in a matrix. The multiple redistribution patterns Pa arranged in a matrix are identical to each other.

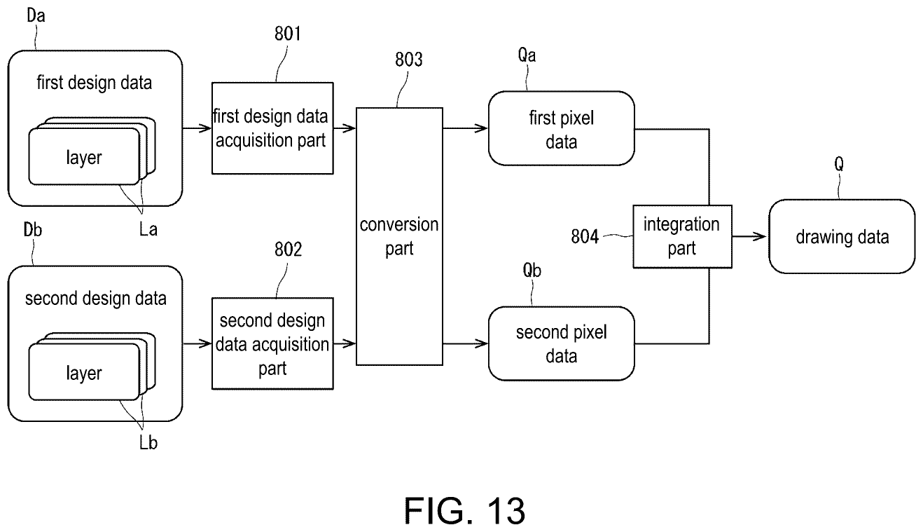

The first design data Da includes one or more layers La (FIG. 13). Each layer La is associated with any gradation value G. In the case where the first design data Da includes multiple layers La, each of the layers La is associated with a mutually different gradation value G.

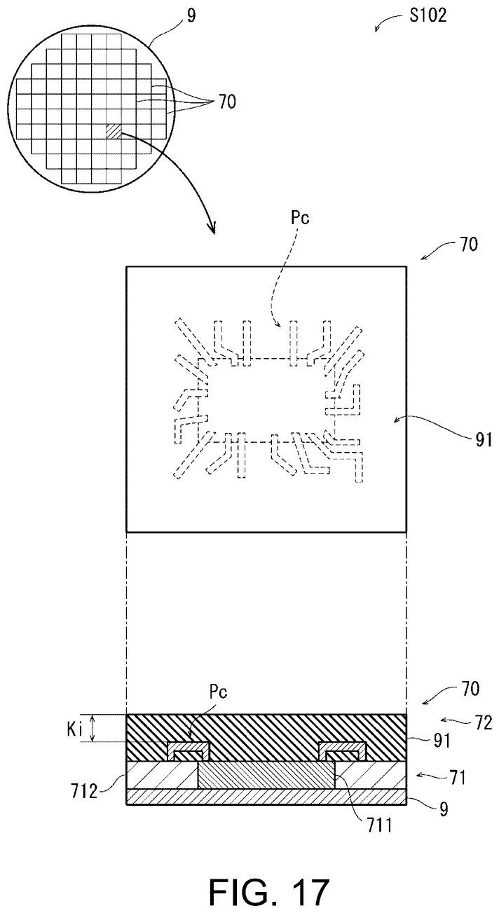

The first design data Da includes one or more layers La associated with the gradation values G equal to or greater than the reference gradation value Gi (first gradation value range Ga). However, here, the thickness of the portion of the resist film 91 covering the lower wiring pattern Pc (that is, the dimension from the surface of the resist film 91 to the lower wiring pattern Pc) is called “reference thickness Ki” (FIG. 17), and the minimum gradation value G among the gradation values G where the aperture depth K becomes equal to or greater than the reference thickness Ki is called “reference gradation value Gi” (FIG. 7 to FIG. 9). For example, in the case where the reference gradation value Gi is “4”, the first design data Da includes at least one of the layer La associated with the gradation value G “4” and the layer La associated with the gradation value G “5”. However, the first design data Da may further include layers La associated with gradation values G smaller than the reference gradation value Gi. For example, in the case where the reference gradation value Gi is “4”, the first design data Da may further include layers La associated with any of the gradation values G “1”, “2”, or “3”.

### (First Pixel Data Qa)

The first pixel data Qa is data obtained by converting the first design data Da to raster data (data in a raster format). That is, in the first pixel data Qa, the redistribution pattern Pa (specifically, the position, shape, dimensions, etc., of the redistribution pattern Pa) is described in a raster format.

In the first pixel data Qa, pixels (dots) derived from each layer La included in the first design data Da are assigned the gradation value G associated with the layer La. Specifically, for example, each layer La included in the first design data Da becomes two-gradation pixel data of the gradation value G associated with the layer La and the gradation value G “0”. In the case where the first design data Da includes one layer La, the two-gradation pixel data obtained from the layer La becomes the first pixel data Qa. On the other hand, in the case where the first design data Da includes multiple layers La, multiple two-gradation pixel data obtained from the multiple layers La are integrated to become the first pixel data Qa. In this case, the first pixel data Qa becomes multi-gradation pixel data.

As described above, the first design data Da includes one or more layers La associated with gradation values G equal to or greater than the reference gradation value Gi. Therefore, the first pixel data Qa includes pixels assigned gradation values G equal to or greater than the reference gradation value Gi.

In the case where the first design data Da includes one layer La, the first pixel data Qa becomes two-gradation pixel data in which all pixels describing the redistribution pattern Pa (pixels other than pixels with gradation value G “0”) are assigned the same gradation value G (any gradation value G equal to or greater than the reference gradation value Gi). On the other hand, in the case where the first design data Da includes multiple layers La, the first pixel data Qa becomes multi-gradation pixel data in which pixels describing the redistribution pattern Pa include pixels assigned mutually different gradation values G (however, at least one gradation value G is equal to or greater than the reference gradation value Gi).

### (Second Design Data Db)

The second design data Db is the design data of a code pattern Pb. The “code pattern Pb” is a pattern representing an identification code (ID code) for identifying the device 70. That is, the code pattern Pb is a unique pattern individually assigned to the device 70, and specifically includes, for example, a two-dimensional code (QR code), a one-dimensional code (bar code), an array of symbols (characters, numbers, etc.), a combination thereof, and the like.

The second design data Db is vector data. That is, in the second design data Db, the code pattern Pb (specifically, the position, shape, dimensions, etc., of the code pattern Pb) is described in a vector format. As an example, the second design data Db is CAD data generated using CAD. As described above, here, multiple devices 70 are manufactured on one substrate 9 (FIG. 19). Therefore, in the second design data Db, multiple code patterns Pb to be formed on one device 70 are described, for example, as being arranged in a matrix. Needless to say, all of the multiple code patterns Pb arranged in the matrix are different from each other.

Here, in the case where a position that overlaps (interferes) with the redistribution pattern Pa on the resist film 91 according to a plan view of the substrate 9 is called an “interference region 91a” (FIG. 19), the code pattern Pb is prohibited from being disposed in the interference region 91a. That is, the position, the shape, the dimensions, etc., of the code pattern Pb are designed so that the code pattern Pb is disposed at a position avoiding the interference region 91a (that is, a position that does not overlap (interfere) with the redistribution pattern Pa on the resist film 91 according to a plan view of the substrate 9). Also, when a position that overlaps (overlaps) with the lower wiring pattern Pc according to a plan view of the substrate 9 is called an “overlap region 91b” (FIG. 19), the code pattern Pb is allowed to be disposed in the overlap region 91b. That is, it is allowed that the position, shape, dimensions, etc., of the code pattern Pb are designed so that the code pattern Pb is disposed in the overlap region 91b. Therefore, in designing the code pattern Pb, it is not necessary to consider the lower wiring pattern Pc. In other words, the position, shape, dimensions, etc., of the code pattern Pb are not constrained by the lower wiring pattern Pc.

The second design data Db includes one or more layers Lb, similar to the first design data Da (FIG. 13). Each layer Lb is associated with any gradation value G. In the case where the second design data Db includes multiple layers Lb, the respective layers Lb are associated with different gradation values G from each other.

All of the layers Lb included in the second design data Db are associated with gradation values G smaller than the reference gradation value Gi (second gradation value range Gb). That is, the second design data Db includes layers Lb associated with gradation values G smaller than the reference gradation value Gi, and does not include layers Lb associated with gradation values G equal to or greater than the reference gradation value Gi. For example, in the case where the reference gradation value Gi is “4”, the second design data Db includes layers Lb associated with any of gradation values G “1”, “2”, “3”, and does not include layer La associated with gradation value G “4” and layer Lb associated with gradation value G “5”.

### (Second Pixel Data Qb)

The second pixel data Qb is data obtained by converting the second design data Db to raster data. That is, in the second pixel data Qb, the code pattern Pb (specifically, the position, shape, dimensions, etc., of the code pattern Pb) is described in a raster format.

In the second pixel data Qb, the gradation values G associated with the layers Lb are assigned to pixels (dots) derived from the respective layers Lb included in the second design data Db. Specifically, for example, each layer Lb included in the second design data Db becomes two-gradation pixel data of the gradation value G associated with the layer Lb and the gradation value G “0”. In the case where the second design data Db includes one layer Lb, the two-gradation pixel data obtained from the layer Lb becomes the second pixel data Qb. On the other hand, in the case where the second design data Db includes multiple layers Lb, multiple two-gradation pixel data obtained from the multiple layers Lb are integrated to become the second pixel data Qb. In this case, the second pixel data Qb becomes multi-gradation pixel data.

As described above, the second design data Db includes layers Lb associated with gradation values G smaller than the reference gradation value Gi, and does not include layers Lb associated with gradation values G equal to or greater than the reference gradation value Gi. Therefore, the second pixel data Qb includes pixels assigned with gradation values G smaller than the reference gradation value Gi, and does not include pixels assigned with gradation values G equal to or greater than the reference gradation value Gi. That is, all pixels included in the second pixel data Qb are assigned with gradation values G smaller than the reference gradation value Gi.

In the case where the second design data Db includes one layer Lb, the second pixel data Qb becomes two-gradation pixel data in which the same gradation value G (any gradation value G smaller than the reference gradation value Gi) is assigned to all pixels describing the code pattern Pb (pixels other than gradation value G “0”). On the other hand, in the case where the second design data Db includes multiple layers Lb, the second pixel data Qb becomes multi-gradation pixel data in which pixels describing the code pattern Pb include pixels assigned with mutually different gradation values G (however, all gradation values G are smaller than the reference gradation value Gi).

### (Drawing Data Q)

The drawing data Q is data obtained by integrating the first pixel data Qa and the second pixel data Qb into one data. Therefore, the drawing data Q includes pixels derived from the first pixel data Qa (that is, pixels describing the redistribution pattern Pa) and pixels derived from the second pixel data Qb (that is, pixels describing the code pattern Pb). In other words, the drawing data Q includes the redistribution pattern Pa and the code pattern Pb. Therefore, by performing a drawing operation based on the drawing data Q, the redistribution pattern Pa and the code pattern Pb are drawn on the substrate 9 (specifically, the resist film 91).

As described above, in the second design data Db, the position, shape, dimensions, and other aspects of the code pattern Pb are designed so that the code pattern Pb is arranged at a position that avoids the interference region 91a. Therefore, in the drawing data Q, pixels describing the redistribution pattern Pa and pixels describing the code pattern Pb are not arranged to overlap at the same position, and the redistribution pattern Pa and the code pattern Pb are arranged at positions that do not overlap with each other. Therefore, in the drawing operation based on the drawing data Q, the redistribution pattern Pa and the code pattern Pb are drawn at positions that do not overlap with each other on the resist film 91.

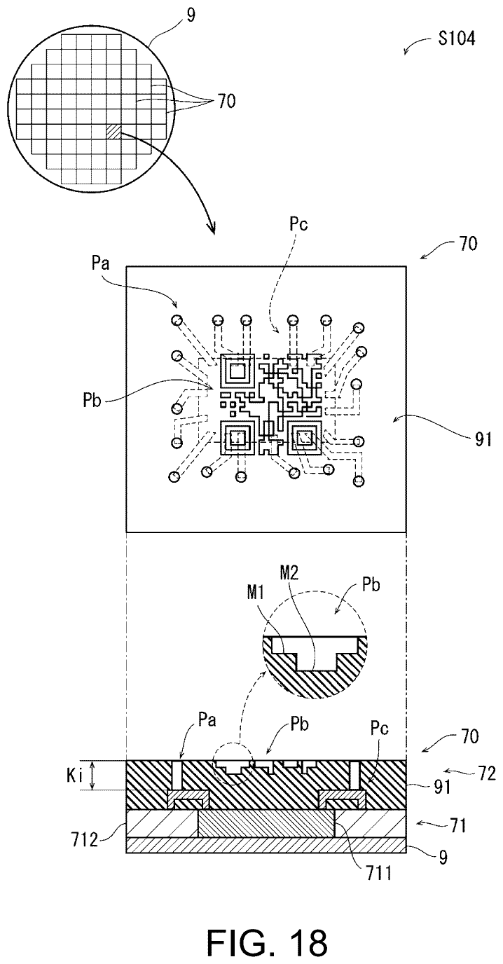

Also, as described above, the first pixel data Qa includes pixels assigned with gradation values G equal to or greater than the reference gradation value Gi. Therefore, in the drawing data Q, at least a portion of the pixels describing the redistribution pattern Pa are assigned with gradation values G equal to or greater than the reference gradation value Gi. Therefore, in the drawing operation based on the drawing data Q, at least a portion of the redistribution pattern Pa is drawn with gradation values G equal to or greater than the reference gradation value Gi. At positions drawn with gradation values G equal to or greater than the reference gradation value Gi, the aperture depth K (the aperture depth K of an aperture formed at that position by performing development) becomes equal to or greater than the reference thickness Ki. In other words, the aperture corresponding to the redistribution pattern Pa formed by performing development has at least a portion penetrating through the portion of the resist film 91 covering the lower wiring pattern Pc in the thickness direction (FIG. 18).

Also, in the case where the first pixel data Qa is two-gradation pixel data, in the drawing data Q, the same gradation value G is assigned to all pixels describing the redistribution pattern Pa. In this case, in the drawing operation based on the drawing data Q, the entire redistribution pattern Pa is drawn with a single gradation value G. As a result, the apertures corresponding to the redistribution pattern Pa formed by performing development have the same depth throughout. On the other hand, in the case where the first pixel data Qa is multi-gradation pixel data, in the drawing data Q, pixels describing the redistribution pattern Pa include those assigned with mutually different gradation values G. In this case, in the drawing operation based on the drawing data Q, the redistribution pattern Pa is drawn with multiple gradations. As a result, the apertures corresponding to the redistribution pattern Pa formed by performing development include portions having mutually different depths.

On the other hand, as described above, all pixels included in the second pixel data Qb are assigned with gradation values G smaller than the reference gradation value Gi. Therefore, in the drawing data Q, all pixels describing the code pattern Pb are assigned with gradation values G smaller than the reference gradation value Gi. Therefore, in the drawing operation based on the drawing data Q, the entire code pattern Pb is drawn with gradation values G smaller than the reference gradation value Gi. At positions drawn with gradation values G smaller than the reference gradation value Gi, the aperture depth K (the aperture depth K of an aperture formed at the position by performing development) becomes smaller than the reference thickness Ki. In other words, the apertures corresponding to the code pattern Pb formed by performing development have depths so that the entirety thereof does not reach the lower wiring pattern Pc (FIG. 18).

Also, in the case where the second pixel data Qb is two-gradation pixel data, in the drawing data Q, the same gradation value G is assigned to all pixels describing the code pattern Pb. In this case, in the drawing operation based on the drawing data Q, the entire code pattern Pb is drawn with a single gradation value G. As a result, the apertures corresponding to the code pattern Pb formed by performing development have the same depth throughout. On the other hand, in the case where the second pixel data Qb is multi-gradation pixel data, in the drawing data Q, pixels describing the code pattern Pb include those assigned with mutually different gradation values G. In this case, in the drawing operation based on the drawing data Q, the code pattern Pb is drawn with multiple gradations. As a result, the apertures corresponding to the code pattern Pb formed by performing development include portions having mutually different depths.

### Configuration Related to Generation of Drawing Data Q

The configuration related to generation of the drawing data Q will be described with reference to FIG. 13. FIG. 13 is a diagram showing the configuration related to generation of the drawing data Q.

The drawing device 100 includes, as a configuration related to generation of the drawing data Q, a first design data acquisition part 801, a second design data acquisition part 802, a conversion part 803, and an integration part 804. Each of the parts is a functional block realized in the control part 8. Each of the parts may be realized in the control part 8 by the arithmetic processing part 81 executing a program, or may be realized by hardware, such as a dedicated logic circuit.

### (First Design Data Acquisition Part 801)

The first design data acquisition part 801 acquires the first design data Da. The manner in which the first design data acquisition part 801 acquires the first design data Da may be any manner. For example, the first design data acquisition part 801 may acquire the first design data Da by receiving the first design data Da from the design device 200 (specifically, for example, a CAD device for designing the first design data Da) through the communication part 83 (FIG. 3). Alternatively, the first design data acquisition part 801 may acquire the first design data Da by receiving the first design data Da through the input reception part 86 (for example, reading the first design data Da with a recording medium reading device).

### (Second Design Data Acquisition Part 802)

The second design data acquisition part 802 acquires the second design data Db. The manner in which the second design data acquisition part 802 acquires the second design data Db may be any manner. For example, the second design data acquisition part 802 may acquire the second design data Db by receiving the second design data Db from the design device 200 (specifically, for example, a CAD device for designing the second design data Db) through the communication part 83 (FIG. 3). Alternatively, the second design data acquisition part 802 may acquire the second design data Db by receiving the second design data Db through the input reception part 86 (for example, reading the second design data Db with a recording medium reading device).

### (Conversion Part 803)

The conversion part 803 rasterizes each of the first design data Da and the second design data Db (for example, RIP processing) to convert the first design data Da and the second design data Db into raster data. That is, the conversion part 803 rasterizes the first design data Da to acquire first pixel data Qa. Also, the conversion part 803 rasterizes the second design data Db to acquire second pixel data Qb.

### (Integration Part 804)

The integration part 804 integrates (combines) the first pixel data (first data) Qa and the second pixel data (second data) Qb into one data to generate the drawing data Q. The integration is performed, for example, by merge processing.

(iii) Generation Processing of Drawing Data Q

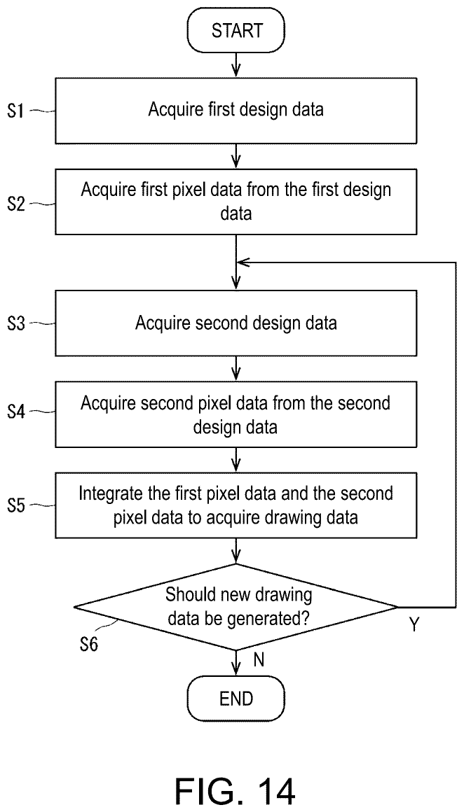

The flow of processing related to generation of the drawing data Q will be described with reference to FIG. 14. FIG. 14 is a diagram showing the flow of processing related to generation of the drawing data Q.

While generating the drawing data Q, first, the first design data acquisition part 801 acquires the first design data Da (first design data acquisition step: Step S1). As described above, the first design data Da is data in which the redistribution pattern Pa is described in a vector format (data including the redistribution pattern Pa), and multiple redistribution patterns Pa corresponding to the respective devices 70 manufactured on one substrate 9 are described in multiple arrangements, for example, in a matrix (FIG. 10).

Subsequently, the conversion part 803 rasterizes the first design data Da acquired in Step S1 to acquire the first pixel data Qa (first pixel data acquisition step: Step S2). As described above, the first pixel data Qa is data in which the redistribution pattern Pa is described in a raster format (data including the redistribution pattern Pa), and includes pixels assigned the gradation value G equal to or greater than the reference gradation value Gi.

On the other hand, the second design data acquisition part 802 acquires the second design data Db (second design data acquisition step: Step S3). As described above, the second design data Db is data in which the code pattern Pb is described in a vector format (data including the code pattern Pb), and multiple code patterns Pb corresponding to the respective devices 70 manufactured on one substrate 9 are described in multiple arrangements, for example, in a matrix (FIG. 11). The processing of step S3 may be performed prior to the processing of Step S1, or may be performed in parallel with the processing of Step S1.

Subsequently, the conversion part 803 rasterizes the second design data Db acquired in Step S3 to acquire the second pixel data Qb (second pixel data acquisition step: Step S4). As described above, the second pixel data Qb is data in which the code pattern Pb is described in a raster format (data including the code pattern Pb), and all pixels included therein are assigned the gradation value G smaller than the reference gradation value Gi.

Subsequently, the integration part 804 integrates the first pixel data Qa acquired in Step S2 and the second pixel data Qb acquired in Step S4 into one data (integration step: Step S5). In this way, the drawing data Q including the redistribution pattern Pa and the code pattern Pb is generated (FIG. 12).

As described above, the drawing data Q includes the redistribution pattern Pa and the code pattern Pb. Therefore, by performing a drawing operation based on the drawing data Q, the redistribution pattern Pa and the code pattern Pb are drawn on the substrate 9 (specifically, on the resist film 91). As described above, in the drawing device 100, when the drawing operation for one substrate 9 ends, a drawing operation for another new substrate 9 is subsequently performed. That is, the drawing operation is repeatedly performed multiple times while exchanging the substrate 9. In many cases, the devices 70 of the same type are manufactured on multiple substrates 9 (for example, multiple substrates 9 belonging to the same lot). The same redistribution pattern Pa is formed on the devices 70 of the same type. Therefore, if only the redistribution pattern Pa is drawn, the same drawing data Q is used in the drawing operation for each of the substrates 9. However, here, in the drawing operation, in addition to the redistribution pattern Pa, the code pattern Pb which is an identification code of the device 70 is drawn. Therefore, mutually different drawing data Q are used in the drawing operations for the respective multiple substrates 9. That is, the drawing operation for each substrate 9 is performed by using the drawing data Q individually generated for each substrate 9. Therefore, after one drawing data Q is generated, it is subsequently determined (repetition determination step: Step S6) whether new drawing data Q (for example, new drawing data Q used for a drawing operation for another substrate 9 of the same lot) is supposed to be generated.

In the case where it is determined that new drawing data Q is supposed to be generated (YES in Step S6), the processing of Step S3 is performed again. That is, the second design data acquisition part 802 acquires new second design data Db (Step S3). In the new second design data Db as well, similarly to the previously acquired second design data Db, the code patterns Pb corresponding to the respective devices 70 manufactured on one substrate 9 are described in multiple arrangements, for example, in a matrix configuration. However, all of the code patterns Pb described in the new second design data Db differ from each other, and do not match any of the multiple code patterns Pb that are described in the previously acquired second design data Db.

Subsequently, the conversion part 803 rasterizes the new second design data Db acquired in Step S3 to acquire new second pixel data Qb (Step S4). Needless to say, all of the code patterns Pb described in the new second pixel data Qb differ from each other, and do not match any of the multiple code patterns Pb that are described in the previously acquired second pixel data Qb.

Subsequently, the integration part 804 integrates the first pixel data Qa acquired in Step S2 (that is, the first pixel data Qa used for generating the previously acquired drawing data Q) and the new second pixel data Qb acquired in Step S4 (that is, the new second pixel data Qb different from the second pixel data Qb used for generating the previously acquired drawing data Q) into one data to generate new drawing data Q (Step S5). That is, the previously acquired drawing data Q and the new drawing data Q are generated by using the same (common) first pixel data Qa. In other words, the first pixel data Qa is shared between the previously acquired drawing data Q and the new drawing data Q. Therefore, the new drawing data Q is one in which only the code pattern Pb has been rewritten from the previously acquired drawing data Q. Accordingly, by performing a drawing operation based on the new drawing data Q, the same redistribution pattern Pa as that drawn on the previous substrate 9 and a code pattern Pb different from that drawn on the previous substrate 9 are drawn on the new substrate 9 (specifically, the resist film 91).

In the case where new drawing data Q is not supposed to be generated (NO in Step S6), the processing related to the generation of the drawing data Q is terminated.

### 4. Device Manufacturing

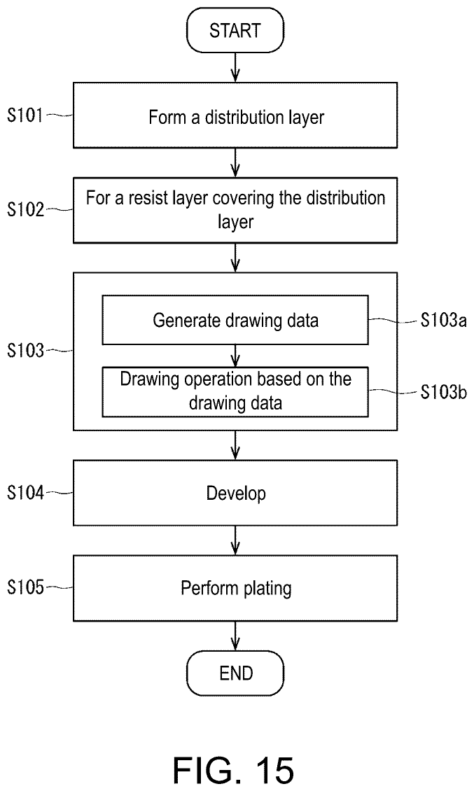

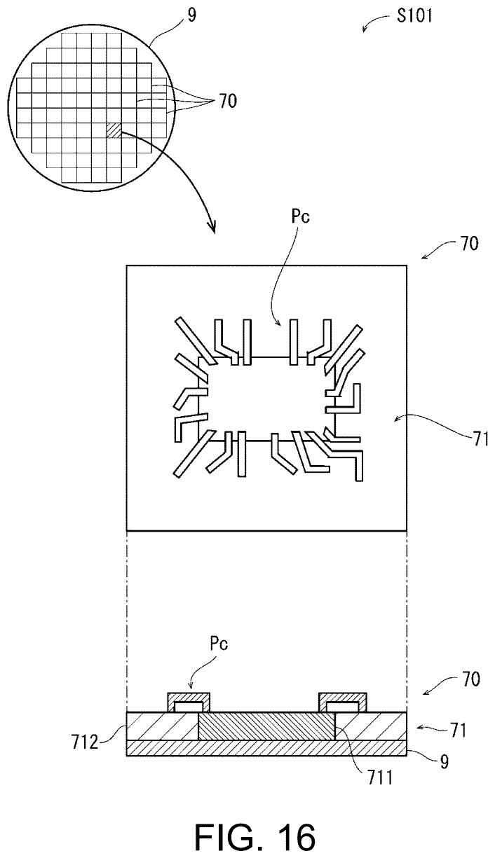

Next, the processes related to the manufacturing of the device 70 are described with reference to FIG. 15 to FIG. 19. FIG. 15 is a diagram showing the flow of processes related to the manufacturing of the device 70. FIG. 16 to FIG. 19 are diagrams for describing each process related to the manufacturing of the device 70.

### (Step S101)

In the manufacturing the device 70, first, the wiring layer 71 is formed on the substrate 9 (wiring layer formation process) (FIG. 16). The lower wiring pattern Pc is formed in the wiring layer 71. The manner of forming the wiring layer 71 and the manner of forming the lower wiring pattern Pc in the wiring layer 71 may be any manner.

### (Step S102)

Subsequently, the resist film 91 is provided on the wiring layer 71 (resist film formation process) (FIG. 17). That is, the resist film 91 is formed to cover the wiring layer 71 in which the lower wiring pattern Pc is formed. The resist film 91 is formed of a photosensitive material (here, a positive-type photosensitive material). Also, the resist film 91 serves as an interlayer insulating film and is formed of an insulating material. That is, the resist film 91 is a photosensitive insulating film (photosensitive insulating film).

### (Step S103)

Subsequently, a pattern is drawn on the resist film 91. Specifically, first, the drawing data Q is generated (drawing data generation process: Step S103a). The flow of processing related to the generation of the drawing data Q is as described above (FIG. 14). Subsequently, a drawing operation is performed based on the generated drawing data Q (drawing process: Step S103b). The specific manner of the drawing operation is as described above (FIG. 4). That is, in the drawing operation, while the drawing head 62 and the stage 3 are relatively moved, the modulated light is formed in the drawing head 62 by applying the spatial modulation according to the drawing data Q to incident light, and by irradiating the modulated light to the substrate 9 (specifically, the resist film 91), the pattern described in the drawing data Q is drawn on the resist film 91.

As described above, the drawing data Q includes the redistribution pattern Pa and the code pattern Pb. Therefore, by performing the drawing operation based on the drawing data Q, the redistribution pattern Pa and the code pattern Pb are drawn on the resist film 91. That is, at the time of drawing the redistribution pattern Pa, the code pattern Pb is also drawn. However, in the drawing data Q, the redistribution pattern Pa and the code pattern Pb are arranged at positions that do not overlap with each other. Therefore, in the drawing operation based on the drawing data Q, the redistribution pattern Pa and the code pattern Pb are drawn at positions that do not overlap with each other on the resist film 91.

Also, in the drawing data Q, at least a portion of the pixels describing the redistribution pattern Pa are assigned the gradation values G equal to or greater than the reference gradation value Gi, and all of the pixels describing the code pattern Pb are assigned the gradation values G smaller than the reference gradation value Gi. Therefore, in the drawing operation based on the drawing data Q, at least a portion of the redistribution pattern Pa is drawn with the gradation values G equal to or greater than the reference gradation value Gi, and the entirety of the code pattern Pb is drawn with the gradation values G smaller than the reference gradation value Gi.

Also, in the drawing data Q, in the case where the same gradation value G is assigned to all of the pixels describing the redistribution pattern Pa, in the drawing operation based on the drawing data Q, the entirety of the redistribution pattern Pa is drawn with a single gradation value G. On the other hand, in the drawing data Q, in the case where the pixels describing the redistribution pattern Pa includes the mutually different gradation values G that are assigned, in the drawing operation based on the drawing data Q, the redistribution pattern Pa is drawn with multiple gradations. Similarly, in the drawing data Q, in the case where the same gradation value G is assigned to all of the pixels describing the code pattern Pb, in the drawing operation based on the drawing data Q, the entirety of the code pattern Pb is drawn with a single gradation value G. On the other hand, in the drawing data Q, in the case where the pixels describing the code pattern Pb include the mutually different gradation values G that are assigned, in the drawing operation based on the drawing data Q, the code pattern Pb is drawn with multiple gradations.

### (Step S104)

Subsequently, the resist film 91 is developed (development step) (FIG. 18). The development is specifically performed, for example, by applying a developer to the resist film 91. Here, since the resist film 91 is formed of a positive-type photosensitive material, the positions irradiated with light (exposed positions) in the drawing operation are dissolved through development, and apertures are formed.

As described above, in the drawing operation, the redistribution pattern Pa and the code pattern Pb are drawn on the resist film 91. Therefore, by performing development, apertures corresponding to the redistribution pattern Pa and apertures corresponding to the code pattern Pb are formed in the resist film 91. Also, in the drawing operation, the redistribution pattern Pa and the code pattern Pb are drawn at positions that do not overlap with each other on the resist film 91. Therefore, the apertures corresponding to the redistribution pattern Pa and the apertures corresponding to the code pattern Pb are formed at positions that do not overlap with each other.

Also, as described above, in the drawing operation, at least a portion of the redistribution pattern Pa is drawn with a gradation value G equal to or greater than the reference gradation value Gi, and the entirety of the code pattern Pb is drawn with a gradation value G smaller than the reference gradation value Gi. That is, the maximum gradation value G related to drawing the code pattern Pb is smaller than the maximum gradation value G related to drawing the redistribution pattern Pa. In the case where the resist film 91 is formed of a positive-type photosensitive material, the larger the gradation value G, the larger the exposure amount density E. Therefore, the maximum value of the exposure amount density E for drawing the code pattern Pb is smaller than the maximum value of the exposure amount density E for drawing the redistribution pattern Pa. As a result, the maximum dimension in the depth direction of the apertures corresponding to the code pattern Pb becomes smaller than the maximum dimension in the depth direction of the apertures corresponding to the redistribution pattern Pa. In other words, the exposure amount density E of the modulated light irradiated to the substrate 9 in the drawing operation is adjusted so that the maximum dimension in the depth direction of the apertures corresponding to the code pattern Pb becomes smaller than the maximum dimension in the depth direction of the apertures corresponding to the redistribution pattern Pa.

Also, in the drawing operation, since at least a portion of the redistribution pattern Pa is drawn with a gradation value G equal to or greater than the reference gradation value Gi, the maximum dimension in the depth direction of the apertures corresponding to the redistribution pattern Pa becomes equal to or greater than the reference thickness Ki. In other words, the exposure amount density E of the modulated light irradiated to the substrate 9 in the drawing operation is adjusted so that the maximum dimension in the depth direction of the apertures corresponding to the redistribution pattern Pa becomes equal to or greater than the reference thickness Ki. As described above, the reference thickness Ki is the dimension from the surface of the resist film 91 to the lower wiring pattern Pc. Therefore, the apertures corresponding to the redistribution pattern Pa have at least a portion thereof penetrating through the portion of the resist film 91 that covers the lower wiring pattern Pc in the thickness direction. That is, the lower wiring pattern Pc is exposed in at least at a portion of the bottom of the apertures corresponding to the redistribution pattern Pa.

Also, in the drawing operation, since the entire code pattern Pb is drawn with a gradation value G smaller than the reference gradation value Gi, the maximum dimension in the depth direction of the apertures corresponding to the code pattern Pb becomes a value smaller than the reference thickness Ki. In other words, the exposure amount density E of the modulated light irradiated to the substrate 9 in the drawing operation is adjusted so that the maximum dimension in the depth direction of the apertures corresponding to the code pattern Pb becomes smaller than the reference thickness Ki. Therefore, the apertures corresponding to the code pattern Pb have a depth such that the entirety thereof does not reach the lower wiring pattern Pc (does not break through the bottom). That is, the lower wiring pattern Pc is not exposed at the bottom of the apertures corresponding to the code pattern Pb. For example, in the second design data Db, in the case where the position, shape, dimensions, and the like of the code pattern Pb are designed so that the code pattern Pb is arranged in the overlap region 91b (that is, at a position overlapping with the lower wiring pattern Pc in a plan view of the substrate 9), in the drawing operation, the code pattern Pb is drawn in the overlap region 91b, and the apertures corresponding to the code pattern Pb are formed in the overlap region 91b. Here, since the apertures corresponding to the code pattern Pb have a depth so that the apertures do not reach the lower wiring pattern Pc, even if the apertures corresponding to the code pattern Pb are formed in the overlap region 91b, no influence is exerted on the lower wiring pattern Pc.

Also, in the drawing operation, in the case where the entire redistribution pattern Pa is drawn with a single gradation value G, the apertures corresponding to the redistribution pattern Pa have the same depth throughout. On the other hand, in the drawing operation, in the case where the redistribution pattern Pa is drawn with multiple gradations, the apertures corresponding to the redistribution pattern Pa include portions having different depths from each other. Similarly, in the drawing operation, in the case where the entire code pattern Pb is drawn with a single gradation value G, the apertures corresponding to the code pattern Pb have the same depth throughout. On the other hand, in the drawing operation, in the case where the code pattern Pb is drawn with multiple gradations, the apertures corresponding to the code pattern Pb include a first portion M1 and a second portion M2 that are portions having different depths from each other (portions having different dimensions from each other in the depth direction). In other words, the exposure amount density E of the modulated light irradiated to the substrate 9 in the drawing operation is adjusted so that the apertures corresponding to the code pattern Pb include the portions M1 and M2 having different dimensions from each other in the depth direction.

### (Step S105)

Thereafter, for example, plating is performed on the substrate 9 (plating process) (FIG. 19). In this way, metal (for example, copper) is provided inside each of the redistribution pattern Pa and the code pattern Pb. Specifically, for example, the entire interior of the redistribution pattern Pa and the code pattern Pb is filled with metal, or the inner peripheral walls of the redistribution pattern Pa and the code pattern Pb are covered with metal. By providing metal inside the redistribution pattern Pa, interlayer conduction is ensured. At locations where the redistribution pattern Pa opens on the upper surface of the redistribution layer 72, for example, connection electrodes (for example, bumps) (not shown) are provided. On the other hand, by providing metal inside the code pattern Pb, the visibility of the code pattern Pb is enhanced. However, the visibility of the code pattern Pb can also be ensured even with a concave-convex structure alone. Therefore, it is not required to provide metal inside the code pattern Pb. For example, appropriate masking or the like may be performed in plating so that metal is not provided inside the code pattern Pb.

### 5. Effects

In the above embodiments, generating the drawing data Q including the wiring pattern (redistribution pattern) Pa and the code pattern Pb representing the identification code of the device 70 (drawing data generation process: Step S103a), and irradiating the modulated light spatially modulated according to the drawing data Q to the substrate 9 provided with the photosensitive resist film (resist film) 91 to draw the redistribution pattern Pa and the code pattern Pb on the resist film 91 (drawing process: Step S103b) are included. Here, the redistribution pattern Pa and the code pattern Pb are drawn at positions that do not overlap with each other on the resist film 91. Additionally, among the apertures formed by developing the resist film 91, the exposure amount density E of the modulated light irradiated to the substrate 9 is adjusted so that the maximum dimension in the depth direction of the apertures corresponding to the code pattern Pb becomes smaller than the maximum dimension in the depth direction of the apertures corresponding to the redistribution pattern Pa. According to this configuration, the modulated light spatially modulated according to the drawing data Q including the redistribution pattern Pa and the code pattern Pb is irradiated to the substrate 9, and the redistribution pattern Pa and the code pattern Pb are drawn on the resist film 91. That is, at the time of drawing the redistribution pattern Pa, the code pattern Pb is drawn together. Therefore, an identification code can be assigned to the device 70 without requiring extra time and cost. Additionally, since the redistribution pattern Pa and the code pattern Pb are drawn collectively in the same drawing process, it is guaranteed that the code pattern Pb correctly corresponds to the redistribution pattern Pa. That is, a highly reliable code pattern Pb can be formed.

Additionally, in the above embodiment, the resist film 91 is provided on the wiring layer 71, and the exposure amount density E is adjusted so that the maximum dimension in the depth direction of the aperture corresponding to the code pattern Pb becomes smaller than the dimension (reference thickness Ki) from the surface of the resist film 91 to the lower wiring pattern Pc provided in the wiring layer 71. According to this configuration, among the apertures formed by developing the resist film 91, the aperture corresponding to the code pattern Pb has a depth that does not reach the lower wiring pattern Pc provided in the wiring layer 71. Therefore, even when the aperture corresponding to the code pattern Pb is formed in the overlap region 91b (that is, at a position overlapping with the lower wiring pattern Pc in a plan view of the substrate 9), no influence is exerted on the lower wiring pattern Pc. For this reason, in the second design data Db, designing the position, shape, dimensions, etc., of the code pattern Pb so that the code pattern Pb is arranged in the overlap region 91b (and consequently, in the drawing operation, the code pattern Pb being drawn in the overlap region 91b and the aperture corresponding to the code pattern Pb being formed in the overlap region 91b) is permitted. That is, the position, shape, dimensions, etc., of the code pattern Pb are not constrained by the lower wiring pattern Pc, and the degree of freedom in designing the code pattern Pb increases. As a result, for example, it becomes possible to form a large and easily visible code pattern Pb. Also, for example, it becomes possible to form a complex code pattern Pb that is difficult to counterfeit or tamper with.

Additionally, in the above embodiment, the exposure amount density E may be adjusted so that the aperture corresponding to the code pattern Pb includes portions (the first portion M1 and the second portion M2) having mutually different dimensions in the depth direction. According to the configuration, the shape of the aperture corresponding to the code pattern Pb (that is, the identification code assigned to the device 70) becomes complex, making the identification code difficult to counterfeit or tamper.

Additionally, in the above embodiment, generating the drawing data Q (drawing data generation step: Step S103a) includes integrating (integration step: Step S5) the first pixel data (first data) Qa including the redistribution pattern Pa and the second pixel data (second data) Qb including the code pattern Pb. The first pixel data Qa is shared among multiple drawing data Q. According to this configuration, multiple drawing data Q required in the case of performing drawing on multiple substrates 9 can be efficiently generated.

### Other Embodiments

The configuration and the operation of the drawing device 100 according to the above embodiment can be appropriately modified. In the following description, elements similar to those described in the above embodiment are assigned the same reference numerals and their descriptions are omitted.

### 6-1. Case Where the Resist Film is Formed of a Negative-Type Photosensitive Material

In the above embodiment, the case where the resist film 91 is formed of a positive-type photosensitive material (positive-type resist) is illustrated, but the resist film 91 may also be formed of a negative-type photosensitive material (negative-type resist). In this case, the gradation value table 203 used in performing drawing according to the gradation value G differs from the gradation value table 103 according to the above embodiment.

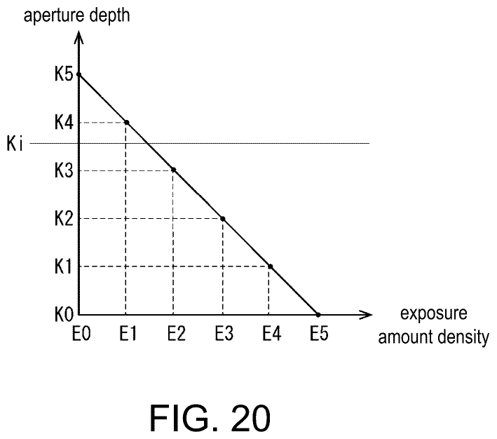

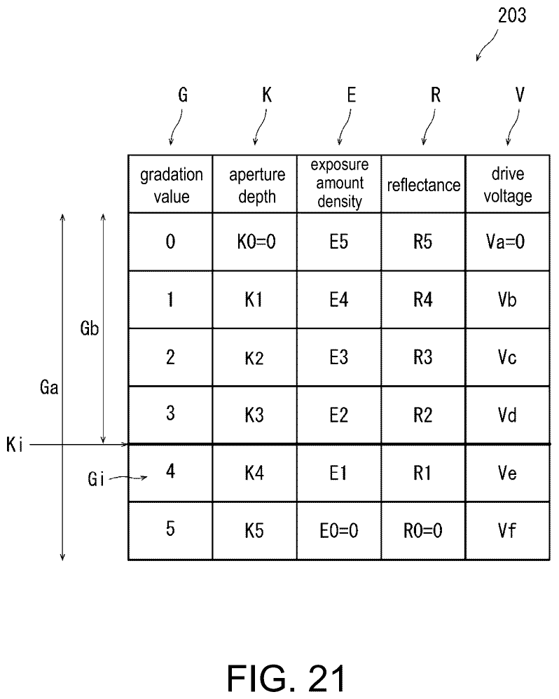

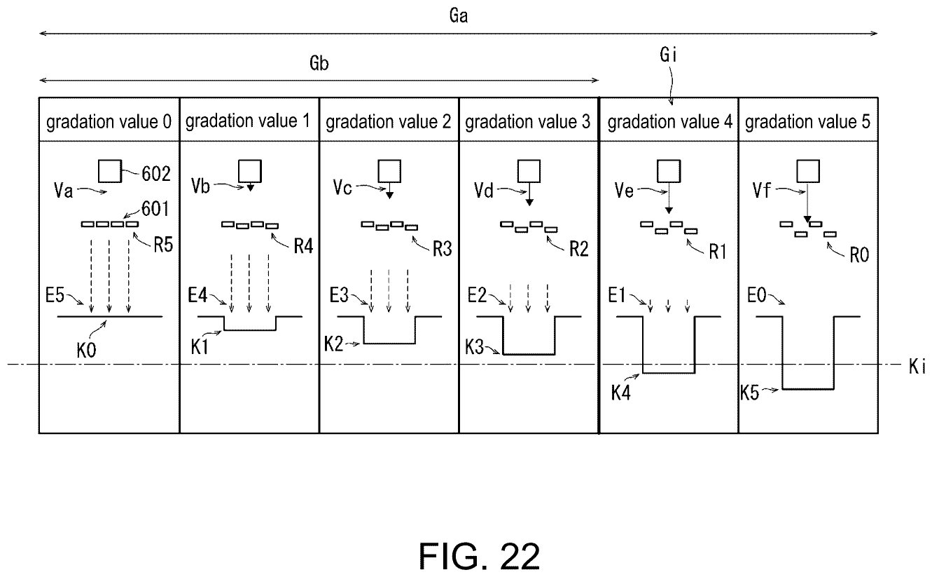

In the case where the resist film 91 is formed of a positive-type photosensitive material, as described in the above embodiment, the aperture depth K increases as the exposure amount density E increases (FIG. 7). Therefore, in the gradation value table 103, the larger each aperture depth K (that is, the aperture depth K associated with each gradation value G), the larger the values of the exposure amount density E and the reflectance R become, and the smaller the value of the drive voltage V becomes (FIG. 8, FIG. 9). Comparatively, in the case where the resist film 91 is formed of a negative-type photosensitive material, the aperture depth K decreases as the exposure amount density E increases (FIG. 20). Therefore, in the gradation value table 203, the larger each aperture depth K (that is, the aperture depth K associated with each gradation value G), the smaller the values of the exposure amount density E and reflectance R become, and the larger the value of the drive voltage V becomes (FIG. 21, FIG. 22).

In the embodiment as well, similar to the above embodiment, during forming of the modulated light, the drive voltage V associated with the gradation value G assigned to the target pixel (that is, the drive voltage V associated with the gradation value G in the gradation value table 203) is applied to the target modulation unit 601. Then, the reflectance R of the target modulation unit 601, and consequently the exposure amount density E of the modulated light irradiated to the target position, follows the gradation value G assigned to the target pixel. In this way, a pattern is drawn at the target position with the gradation value G assigned to the target pixel. As a result, the aperture depth K of the aperture formed at the target position by performing development becomes a value associated with the gradation value G assigned to the target pixel (that is, the value of the aperture depth K associated with the gradation value G in the gradation value table 103).

For example, in the case where the gradation value G assigned to the target pixel is “5”, the maximum voltage Vf is applied to the target modulation unit 601 (the drive voltage V is set to the maximum voltage Vf). At this time, the reflectance R0 of the target modulation unit 601 becomes 0%, no light is irradiated to the target position, and the exposure amount density E0 becomes zero. That is, the exposure amount density E of the modulated light irradiated to the target position becomes the exposure amount density E0 (E0=0) according to the gradation value G “5” assigned to the target pixel. Consequently, the aperture depth K of the aperture formed at the target position by performing development becomes the aperture depth K5 according to the gradation value G “5” assigned to the target pixel.

In the gradation value table 203, in the case where the correspondence is made so that the smaller the gradation value G, the smaller the value of the aperture depth K, the smaller the gradation value G assigned to the target pixel, the smaller the drive voltage V applied to the target modulation unit 601, and the larger the reflectance R of the target modulation unit 601. And the larger the reflectance R becomes, the larger the exposure amount density E of the modulated light irradiated to the target position becomes, and the smaller (shallower) the aperture depth K of the aperture formed at the target position by performing development becomes.

And in the case where the gradation value G assigned to the target pixel is “0”, no drive voltage V is applied to the target modulation unit 601 (the drive voltage V is set to the minimum voltage Va). At this time, the reflectance R5 of the target modulation unit 601 becomes 100%, and the exposure amount density E of the modulated light irradiated to the target position becomes the exposure amount density E5 according to the gradation value G “0” assigned to the target pixel. Therefore, even if development is performed, the resist film 91 at the target position does not dissolve (does not form an aperture), and the aperture depth K of the aperture formed at the target position becomes zero. That is, the aperture depth K of the aperture formed at the target position by performing development becomes the aperture depth K0 (K0=0) according to the gradation value G “0” assigned to the target pixel.

In the embodiment as well, similar to the above embodiment, in the drawing data Q, at least a portion of the pixels describing the redistribution pattern Pa are assigned gradation values G equal to or greater than the reference gradation value Gi (first gradation value range Ga), and all of the pixels describing the code pattern Pb are assigned gradation values G smaller than the reference gradation value Gi (second gradation value range Gb). Therefore, in the drawing operation based on the drawing data Q, at least a portion of the redistribution pattern Pa is drawn with gradation values G equal to or greater than the reference gradation value Gi, and the entire code pattern Pb is drawn with gradation values G smaller than the reference gradation value Gi. That is, the maximum gradation value G related to drawing the code pattern Pb is smaller than the maximum gradation value G related to drawing the redistribution pattern Pa. In the case where the resist film 91 is formed of a negative-type photosensitive material, the larger the gradation value G, the smaller the exposure amount density E. Therefore, the minimum value of the exposure amount density E for drawing the code pattern Pb is larger than the minimum value of the exposure amount density E for drawing the redistribution pattern Pa. As a result, the maximum dimension in the depth direction of the aperture corresponding to the code pattern Pb becomes smaller than the maximum dimension in the depth direction of the aperture corresponding to the redistribution pattern Pa. In other words, the exposure amount density E of the modulated light irradiated to the substrate 9 in the drawing operation is adjusted so that the maximum dimension in the depth direction of the aperture corresponding to the code pattern Pb becomes smaller than the maximum dimension in the depth direction of the aperture corresponding to the redistribution pattern Pa.

Also, in the embodiment as well, similar to the above embodiment, in the drawing operation based on the drawing data Q, at least a portion of the redistribution pattern Pa is drawn with gradation values G equal to or greater than the reference gradation value Gi, so the maximum dimension in the depth direction of the aperture corresponding to the redistribution pattern Pa becomes equal to or greater than the reference thickness Ki. In other words, the exposure amount density E of the modulated light irradiated to the substrate 9 in the drawing operation is adjusted so that the maximum dimension in the depth direction of the aperture corresponding to the redistribution pattern Pa becomes equal to or greater than the reference thickness Ki. Therefore, at least a portion of the aperture corresponding to the redistribution pattern Pa penetrates in the thickness direction through the portion covering the lower wiring pattern Pc in the redistribution layer 72.

Also, in the embodiment as well, similar to the above embodiment, in the drawing operation based on the drawing data Q, the entire code pattern Pb is drawn with gradation values G smaller than the reference gradation value Gi, so the maximum dimension in the depth direction of the aperture corresponding to the code pattern Pb becomes a value smaller than the reference thickness Ki. In other words, the exposure amount density E of the modulated light irradiated to the substrate 9 in the drawing operation is adjusted so that the maximum dimension in the depth direction of the aperture corresponding to the code pattern Pb becomes smaller than the reference thickness Ki. Therefore, the aperture corresponding to the code pattern Pb has a depth such that the entirety thereof does not reach the lower wiring pattern Pc. For this reason, even if the aperture corresponding to the code pattern Pb is formed in the overlap region 91b, the lower wiring pattern Pc is not affected.

### 6-2. Other Embodiments

In each of the above embodiments, after integrating the first design data (first data) Da and the second design data (second data) Db into one data, the data may be rasterized and the obtained data may be acquired as the drawing data Q. In this case, the first design data Da may be shared among multiple drawing data Q.

In each of the above embodiments, the code pattern Pb may be provided on a surface exposed to the outside of the device 70 (for example, the upper surface of the redistribution layer 72), or may be provided on other surfaces (for example, the lower surface of the redistribution layer 72, the upper surface or lower surface of the wiring layer 71). In other words, the code pattern Pb may be provided so as to be embedded in the device 70. In this case, the code pattern Pb may be provided on a surface exposed to the outside at the time of assembling of the device 70, at the time of disassembling the device 70, at the time of inspecting the device 70, and the like.

In each of the above embodiments, the structure of the device 70 may be of any type. For example, another layer (for example, a protective film) may be further provided on the redistribution layer 72.

In each of the above embodiments, the case where the drawing data Q is generated as single image data indicating a pattern to be formed on the entire surface of the substrate 9 is described. However, the drawing data Q may also be generated as image data indicating a pattern to be formed on a portion of the substrate 9. That is, the image data indicating a pattern to be formed on the entire surface of the substrate 9 may be generated as single image data, or may be generated as divided image data.

The relative movement mechanism 4 according to each of the above embodiments is a mechanism that moves the stage 3. However, instead of (or in addition to) the mechanism that moves the stage 3, a mechanism that moves the drawing head 62 may be provided.

In the drawing device 100 according to each of the above embodiments, the spatial light modulator 600 may be configured by using, for example, a digital mirror device (DMD). In this case, multi-gradation drawing can be performed by adjusting at least one of the number of times of light irradiations and the irradiation time in the DMD.

In the drawing device 100 according to each of the above embodiments, the substrate 9 may be, for example, a silicon wafer, a resin substrate, a glass substrate, a quartz substrate, or the like. Additionally, the substrate 9 may be a semiconductor substrate, a printed substrate, a color filter substrate (for example, a color filter substrate for liquid crystal display devices), a glass substrate for photomasks, a glass substrate for liquid crystal displays, a glass substrate for plasma displays, a glass substrate for flat panel displays, a substrate for a field emission display (FED), a substrate for optical disks, a substrate for magnetic disks, a substrate for magneto-optical disks, a substrate for solar cell panels, or the like. Additionally, the substrate 9 may be rectangular or circular. Additionally, the substrate 9 may not be perfectly rectangular or perfectly circular, and may have shape portions such as notches, orientation flats, or the like.

As described above, the drawing method and drawing device have been described in detail, but the above description is illustrative in all aspects and is not limited thereto. It is understood that countless embodiments and modification examples not illustrated can be envisioned without departing from the scope of this disclosure. Additionally, each configuration described in each of the above embodiments and each modification example can be appropriately combined or omitted as long as they do not contradict each other.

The disclosure includes the following aspects.

A first aspect provides a drawing method. The drawing method includes: generating drawing data including a wiring pattern and a code pattern representing an identification code of a device; and irradiating modulated light spatially modulated according to the drawing data to a substrate provided with a photosensitive resist film to draw the wiring pattern and the code pattern on the photosensitive resist film. The wiring pattern and the code pattern are drawn at positions that do not overlap with each other on the photosensitive resist film. An exposure amount density of the modulated light irradiated onto the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.

According to a second aspect, in the drawing method according to the first aspect, the photosensitive resist film is provided on a wiring layer, and the exposure amount density is adjusted such that the maximum dimension in the depth direction of the aperture corresponding to the code pattern is smaller than a dimension from a surface of the photosensitive resist film to a lower wiring pattern provided in the wiring layer.

According to a third aspect, in the drawing method according to the second aspect, the code pattern is drawn at a position that overlaps with the lower wiring pattern when viewed in a plan view.

According to a fourth aspect, in the drawing method according to any one of the first to third aspects, the photosensitive resist film is formed of a positive-type photosensitive material, and a maximum value of the exposure amount density for drawing the code pattern is smaller than a maximum value of the exposure amount density for drawing the wiring pattern.

According to a fifth aspect, in the drawing method according to any one of the first to third aspects, the photosensitive resist film is formed of a negative-type photosensitive material, and a minimum value of the exposure amount density for drawing the code pattern is greater than a minimum value of the exposure amount density for drawing the wiring pattern.

According to a sixth aspect, in the drawing method according to any one of the first to fifth aspects, the exposure amount density is adjusted such that the aperture corresponding to the code pattern comprises portions having mutually different dimensions in the depth direction.

According to a seventh aspect, in the drawing method according to any one of the first to sixth aspects, generating the drawing data includes integrating first data including the wiring pattern and second data including the code pattern, and first data is shared among a plurality of drawing data.

According to an eighth aspect, a drawing device is provided. The drawing device includes: a stage, holding a substrate provided with a photosensitive resist film; a drawing head, forming modulated light spatially modulated according to drawing data that includes a wiring pattern and a code pattern representing an identification code of a device, and irradiating the modulated light to the substrate; a relative movement mechanism, causing a relative movement between the stage and the drawing head; and a control part, causing a relative movement between the drawing head and the stage while causing the drawing head to form the modulated light and irradiate the modulated light to the substrate, thereby drawing the wiring pattern and the code pattern on the photosensitive resist film. The wiring pattern and the code pattern are drawn at positions that do not overlap with each other on the photosensitive resist film. An exposure amount density of the modulated light irradiated to the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.

According to each of the first to eighth aspects, the modulated light spatially modulated according to the drawing data including the wiring pattern and the code pattern is irradiated to the substrate, and the wiring pattern and the code pattern are drawn on the photosensitive resist film. That is, the code pattern is drawn together at the time of drawing the wiring pattern. Therefore, the identification code can be assigned to a device without requiring extra time and cost.

According to the second aspect, among apertures formed by developing the photosensitive resist film, the aperture corresponding to the code pattern has a depth that does not reach the lower wiring pattern provided in the wiring layer. Therefore, the aperture corresponding to the code pattern (that is, the identification code assigned to the device) does not affect the lower wiring pattern.

According to the third aspect, the degree of freedom in designing the code pattern is increased.

According to the sixth aspect, the shape of the aperture corresponding to the code pattern (that is, the identification code assigned to the device) becomes complex, making counterfeiting or tampering of the identification code difficult.

According to the seventh aspect, multiple drawing data required in the case of performing drawing on multiple substrates can be efficiently generated.

What is claimed is:

1. A drawing method, comprising:
generating drawing data comprising a wiring pattern and a code pattern representing an identification code of a device; and
irradiating modulated light spatially modulated according to the drawing data to a substrate provided with a photosensitive resist film to draw the wiring pattern and the code pattern on the photosensitive resist film,
wherein:
the wiring pattern and the code pattern are drawn at positions that do not overlap with each other on the photosensitive resist film, and
an exposure amount density of the modulated light irradiated to the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.

2. The drawing method as claimed in claim 1, wherein:
the photosensitive resist film is provided on a wiring layer, and
the exposure amount density is adjusted such that the maximum dimension in the depth direction of the aperture corresponding to the code pattern is smaller than a dimension from a surface of the photosensitive resist film to a lower wiring pattern provided in the wiring layer.

3. The drawing method as claimed in claim 2, wherein:
the code pattern is drawn at a position that overlaps with the lower wiring pattern when viewed in a plan view.

4. The drawing method as claimed in claim 1, wherein:
the photosensitive resist film is formed of a positive-type photosensitive material, and
a maximum value of the exposure amount density for drawing the code pattern is smaller than a maximum value of the exposure amount density for drawing the wiring pattern.

5. The drawing method as claimed in claim 1, wherein:
the photosensitive resist film is formed of a negative-type photosensitive material, and
a minimum value of the exposure amount density for drawing the code pattern is greater than a minimum value of the exposure amount density for drawing the wiring pattern.

6. The drawing method as claimed in claim 1, wherein:
the exposure amount density is adjusted such that the aperture corresponding to the code pattern comprises portions having mutually different dimensions in the depth direction.

7. The drawing method as claimed in claim 1, wherein:
generating the drawing data comprises integrating first data comprising the wiring pattern and second data comprising the code pattern, and
the first data is shared among a plurality of drawing data.

8. A drawing device, comprising:
a stage, holding a substrate provided with a photosensitive resist film;
a drawing head, forming modulated light spatially modulated according to drawing data that comprises a wiring pattern and a code pattern representing an identification code of a device, and irradiating the modulated light to the substrate;
a relative movement mechanism, causing a relative movement between the stage and the drawing head; and
a control part, causing a relative movement between the drawing head and the stage while causing the drawing head to form the modulated light and irradiate the modulated light to the substrate, thereby drawing the wiring pattern and the code pattern on the photosensitive resist film,
wherein:
the wiring pattern and the code pattern are drawn at positions that do not overlap with each other on the photosensitive resist film, and
an exposure amount density of the modulated light irradiated to the substrate is adjusted such that, among apertures formed by developing the photosensitive resist film, a maximum dimension in a depth direction of an aperture corresponding to the code pattern is smaller than a maximum dimension in a depth direction of an aperture corresponding to the wiring pattern.
